(19) United States
(12) Patent Application Publication
(10) Pub. No.: US 2018/0286731 A1
(43) Pub. Date: Oct. 4, 2018

(54) MANUFACTURING METHOD OF SEMICONDUCTOR DEVICE

(71) Applicant: Renesas Electronics Corporation, Tokyo (JP)

(72) Inventors: Yohei HAMAGUCHI, Ibaraki (JP); Kazuyuki FUJII, Ibaraki (JP); Yosuke INOUE, Ibaraki (JP)

(21) Appl. No.: 15/862,899

(22) Filed: Jan. 5, 2018

(30) Foreign Application Priority Data
Mar. 28, 2017 (JP) 2017-062618

(51) Int. Cl. H01L 21/683; H01L 21/67; G03F 7/20; H01L 21/3065; H01L 21/311

(52) U.S. Cl. CPC H01L 21/6833; H01L 21/67248; H01L 21/31116; G03F 7/70708; H01L 21/3065; H01L 21/67103

(57) ABSTRACT

In order to avoid cracking of a semiconductor wafer when separating the semiconductor wafer from an electrostatic chuck, there is provided a manufacturing method of a semiconductor device including a step of monitoring the potential of the electrostatic chuck from the adsorption starting state of the semiconductor wafer by the electrostatic chuck to the adsorption finishing state thereof. The above step further includes a step of determining the semiconductor wafer to be in the adsorption finishing state when the potential of the electrostatic chuck is within a predetermined range.

### CROSS-REFERENCE TO RELATED APPLICATIONS

The disclosure of Japanese Patent Application No. 2017-062618 filed on Mar. 28, 2017 including the specification, drawings and abstract is incorporated herein by reference in its entirety.

### CROSS-REFERENCE TO RELATED APPLICATIONS

Background

The invention relates to a manufacturing technique of a semiconductor device and particularly, to a technique suitably applied to a manufacturing technique of a semiconductor device having a process of adsorbing a semiconductor wafer by an electrostatic chuck.

Japanese Unexamined Patent Application Publication No. 2003-282691 discloses a technique for running a cooling gas to a rear surface of a semiconductor wafer and checking the adsorbed state of the semiconductor wafer by an electrostatic chuck, according to the flow amount of the cooling gas.

Summary

A semiconductor manufacturing device typified by a dry etching device, a plasma Chemical Vapor Deposition (CVD) device, and a sputtering device performs processing with a semiconductor wafer attracted and fixed to an electrostatic chuck. After finishing the processing, the semiconductor wafer is separated from the electrostatic chuck. Here, since the semiconductor wafer is electrified, charge elimination processing is performed on the semiconductor wafer to eliminate the electric charges on the semiconductor wafer before separating the semiconductor wafer from the electrostatic chuck. In the conventional technique, however, it is difficult to accurately determine whether or not the electric charges have been eliminated from the semiconductor wafer; when the semiconductor wafer is forcedly separated from the electrostatic chuck in an insufficient state of the charge elimination, the semiconductor wafer may be cracked. From the viewpoint of preventing a crack of a semiconductor wafer, when separating the semiconductor wafer from the electrostatic chuck, it should be preferably confirmed that the semiconductor wafer is completely neutralized.

Other problems and novel characteristics will be apparent from the description of the specification and the attached drawings.

A manufacturing method of a semiconductor device according to one embodiment includes a step of monitoring the potential of the electrostatic chuck from an adsorption starting state of a semiconductor wafer by the electrostatic chuck to an adsorption finishing state. The above monitoring step further includes a step of determining the semiconductor wafer to be in the adsorption finishing state when the potential of the electrostatic chuck is within a predetermined range.

According to one embodiment, it is possible to measure the charged state of a semiconductor wafer at a time of eliminating the electric charges from the semiconductor wafer.

### BRIEF DESCRIPTION OF THE DRAWINGS

FIG. 1 is a view showing the state in which an electrostatic chuck adsorbs a semiconductor wafer.

FIG. 2 is a view showing the state in which plasma is used to eliminate charges from the semiconductor wafer.

FIG. 3 is a view showing the state in which the semiconductor wafer is separated from the electrostatic chuck.

FIG. 4 is a view showing the state in which a crack occurs on the semiconductor wafer.

FIG. 5 is a view showing the state of turning on the power source with an electrometer arranged between the electrostatic chuck and the power source.

FIG. 6 is s view showing the state of turning off the power source with the electrometer arranged between the electrostatic chuck and the power source.

FIG. 7 is a view showing the state of performing plasma charge elimination processing with the electrometer arranged between the electrostatic chuck and the power source.

FIG. 8 is a view showing the state of finishing the plasma charge elimination processing with the electrometer arranged between the electrostatic chuck and the power source.

FIG. 9 is a view showing a schematic structure of a semiconductor manufacturing device according to a first embodiment.

FIG. 10 is a view for use in describing an operation of the semiconductor manufacturing device according to the first embodiment.

FIG. 11 is a view for use in describing the operation of the semiconductor manufacturing device following FIG. 10.

FIG. 12 is a view for use in describing the operation of the semiconductor manufacturing device following FIG. 11.

FIG. 13 is a view for use in describing the operation of the semiconductor manufacturing device following FIG. 12.

FIG. 14 is a view for use in describing the operation of the semiconductor manufacturing device following FIG. 13.

FIG. 15 is a view showing one example of the waveform when the electrometer monitors the potential of the electrostatic chuck.

FIG. 16A is a waveform showing a relation between time and monitor voltage and FIG. 16B is a graph showing a relation between power-applied voltage (HV applied voltage) and arriving voltage.

FIG. 17 is a view showing one example of a structure for coupling the semiconductor manufacturing device according to the first embodiment and a charge elimination evaluating device according to the first embodiment.

FIG. 18 is a view showing one example of a hardware structure of the charge elimination evaluating device according to the first embodiment.

FIG. 19 is a view showing a functional block structure of the charge elimination evaluating device according to the first embodiment.

FIG. 20 is a flowchart showing a flow of a charge elimination evaluating method according to the first embodiment.

FIG. 21 is a view showing a functional block structure of a charge elimination evaluating device according to a second embodiment.

FIG. 22 is a flow chart showing a flow of an optimization method of a charge eliminating condition according to the second embodiment.

FIGS. 23A to 23C are views each showing a voltage waveform when the charge elimination processing is performed on a semiconductor wafer under each various charge eliminating condition.

FIG. 24 is a view showing a functional block structure of a charge elimination evaluating device according to a modified example.

FIG. 25 is a flow chart showing a flow of an adjustment method of the charge eliminating condition according to the modified example.

FIG. 26 is a view for use in describing an operation of a semiconductor manufacturing device according to a third embodiment.

FIG. 27 is a view for use in describing the operation of the semiconductor manufacturing device following FIG. 26.

FIG. 28 is a view for use in describing the operation of the semiconductor manufacturing device following FIG. 27.

FIG. 29 is a view for use in describing the operation of the semiconductor manufacturing device following FIG. 28.

FIG. 30 is a voltage waveform showing a potential change of the electrostatic chuck when a “charge elimination with reverse voltage” is normally performed.

FIG. 31 is a view for use in describing an operation of the semiconductor manufacturing device according to the third embodiment.

FIG. 32 is a view for use in the operation of the semiconductor manufacturing device following FIG. 31.

FIG. 33 is a view for use in the operation of the semiconductor manufacturing device following FIG. 32.

FIG. 34 is a voltage waveform showing a potential change of the electrostatic chuck when the “charge elimination with reverse voltage” is insufficient.

FIG. 35 is a view showing a functional block structure of the charge elimination evaluating device according to the third embodiment.

FIG. 36 is a flowchart showing a flow of a charge elimination evaluating method according to the third embodiment.

FIG. 37 is a view showing a schematic structure of a semiconductor manufacturing device according to a fourth embodiment.

FIG. 38 is a view showing together one example of a waveform obtained when the electrometer monitors the potential of a first portion (first electrode) of the electrostatic chuck and one example of a waveform obtained when the electrometer monitors the potential of a second portion (second electrode) of the electrostatic chuck, according to the fourth embodiment.

FIG. 39 is a cross-sectional view showing a manufacturing process of a semiconductor device according to a fifth embodiment.

FIG. 40 is a cross-sectional view showing the above manufacturing process following FIG. 39.

FIG. 41 is a cross-sectional view showing the above manufacturing process following FIG. 40.

FIG. 42 is a cross-sectional view showing the above manufacturing process following FIG. 41.

FIG. 43 is a cross-sectional view showing the above manufacturing process following FIG. 42.

### DETAILED DESCRIPTION

In the following embodiments, a description will be made by dividing into a plurality of sections or embodiments when necessary for the convenience sake, these are not unrelated to each other but are related to each other such that one covers some or all of modifies examples, details, supplemental explanation and so forth of the other unless otherwise clearly specified.

In addition, in the following embodiments, when the number of elements (including the number of units, a numerical value, an amount, a range and the like) is referred to, it is not limited to the specific number but may be more than or not more than the specific number unless otherwise clearly specified and unless otherwise definitely restricted to the specific number in principle.

In addition, in the following embodiments, the constitutional element (including an element step) is not necessarily indispensable unless otherwise clearly specified and unless otherwise thought to be clearly indispensable in principle.

Similarly, in the following embodiments, when the shapes of the constitutional elements and their positional relationship are referred to, the ones that are substantially approximate or similar to the shapes will be included unless otherwise clearly specified and unless otherwise clearly thought that it is not so in principle. The same also applies to the above-mentioned number and range.

In all of the drawings depicted in order to describe the embodiments, the same codes are assigned to the same members and the repetitive description thereof is omitted. Further, hatching may be added to make a view easy to understand even in a plan view.

### First Embodiment

### <Examination for Improvement>

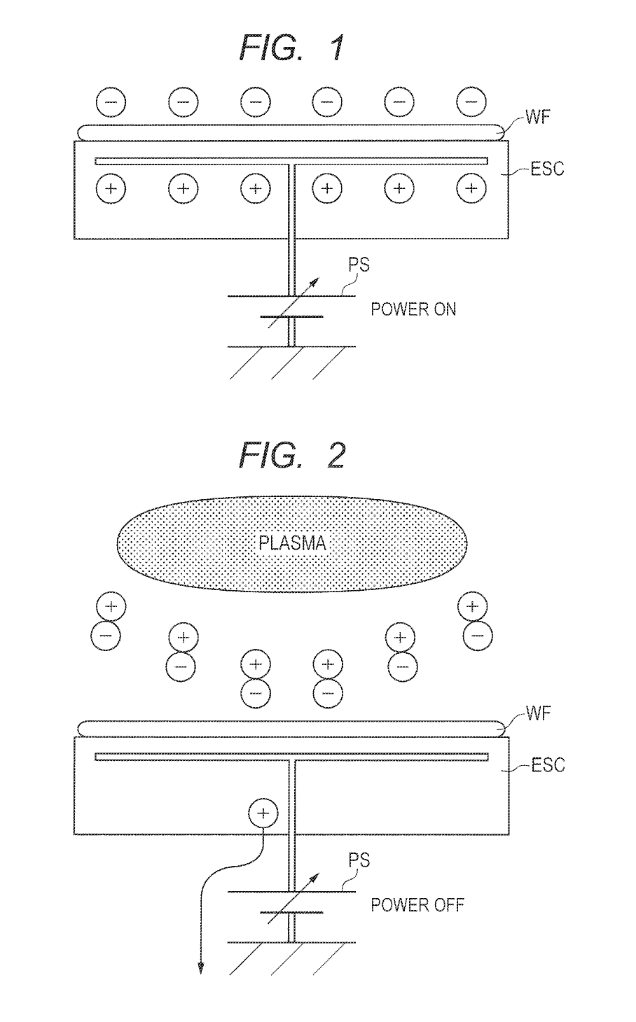

For example, in a semiconductor manufacturing device used in a manufacturing process of a semiconductor device, processing is performed on a semiconductor wafer with the semiconductor wafer attracted and fixed to an electrostatic chuck using electrostatic force. Specifically, FIG. 1 is a view schematically showing the state in which an electrostatic chuck ESC adsorbs a semiconductor wafer WF. As shown in FIG. 1, the electrostatic chuck ESC is electrically coupled to a power source PS and by turning on the power source PS, the electrostatic chuck ESC is charged with plus charges. Minus charges are induced to the semiconductor wafer WF arranged on the electrostatic chuck ESC. As the result, as shown in FIG. 1, electrostatic attraction between the plus charges generated in the electrostatic chuck ESC and the minus charges induced to the semiconductor wafer WF fixes the semiconductor wafer WF to the electrostatic chuck ESC. Thus, with the semiconductor wafer WF fixed to the electrostatic chuck ESC, the semiconductor wafer WF is processed.

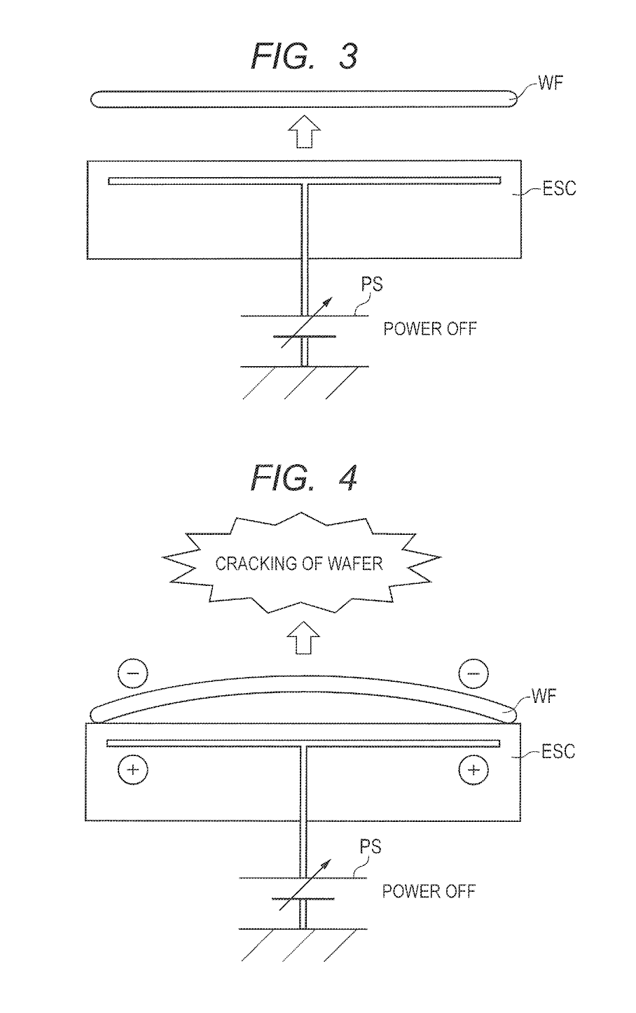

Then, after finishing the processing in the semiconductor manufacturing device, the semiconductor wafer WF has to be separated from the electrostatic chuck ESC in order to carry out the semiconductor wafer WF from the semiconductor manufacturing device. Therefore, for example, as shown in FIG. 2, plasma is generated above the semiconductor wafer WF, the plus charges caused by the plasma and the minus charges included to the semiconductor wafer WF are neutralized, hence to eliminate the minus charges charged on the semiconductor wafer WF. Here, the power source PS electrically coupled to the electrostatic chuck ESC is turned off, the electrostatic chuck ESC is coupled to the ground, and the plus charges flow from the electrostatic chuck ESC to the ground according as the minus charges are eliminated from the semiconductor wafer WF. According to this, as shown in FIG. 3, the electrostatic attraction working between the semiconductor wafer WF and the electrostatic chuck ESC disappears, which makes it easy to separate the semiconductor wafer WF from the electrostatic chuck ESC.

In the examination by the inventor el al., however, it is newly found that the current technique is hard to accurately determine whether or not the charge elimination of the semiconductor wafer WF is finished, and that, for example, as shown in FIG. 4, in an insufficient state of the charge elimination, when the semiconductor wafer WF is forcedly separated from the electrostatic chuck ESC, the semiconductor wafer WF may be cracked. According to this, from the viewpoint of improving the manufacturing yield of a semiconductor device by avoiding cracking of the semiconductor wafer WF, it should be desirably confirmed that the semiconductor wafer WF is completely neutralized, when separating the semiconductor wafer WF from the electrostatic chuck ESC.

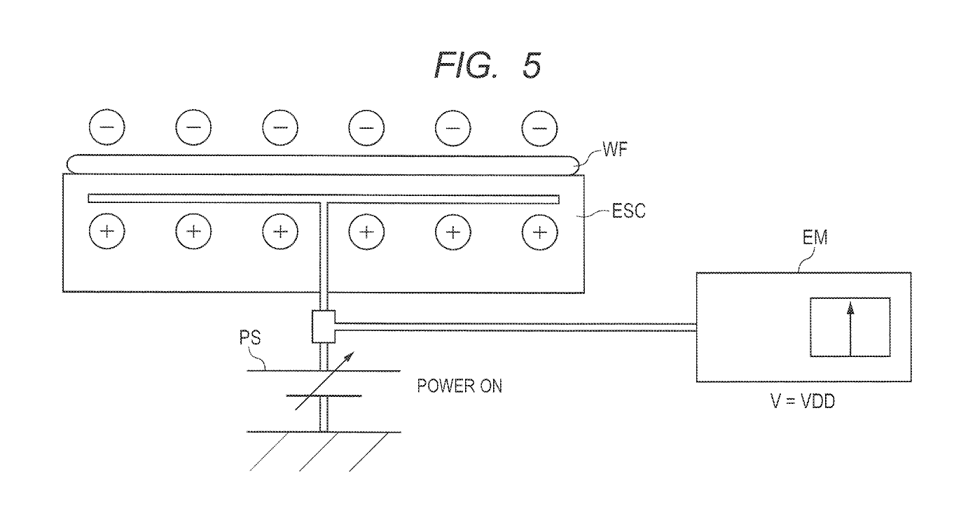

In order to determine whether the semiconductor wafer WF is charged or not, an electrometer EM is set between the electrostatic chuck ESC and the power source PS, for example, as shown in FIG. 5, to monitor the potential of the electrostatic chuck ESC; according to this, the charged state of the semiconductor wafer WF can be indirectly grasped. However, monitoring the potential of the electrostatic chuck ESC just by arranging the electrometer EM between the electrostatic chuck ESC and the power source PS is not enough to accurately determine whether or not the electric charges of the semiconductor wafer WF are completely eliminated.

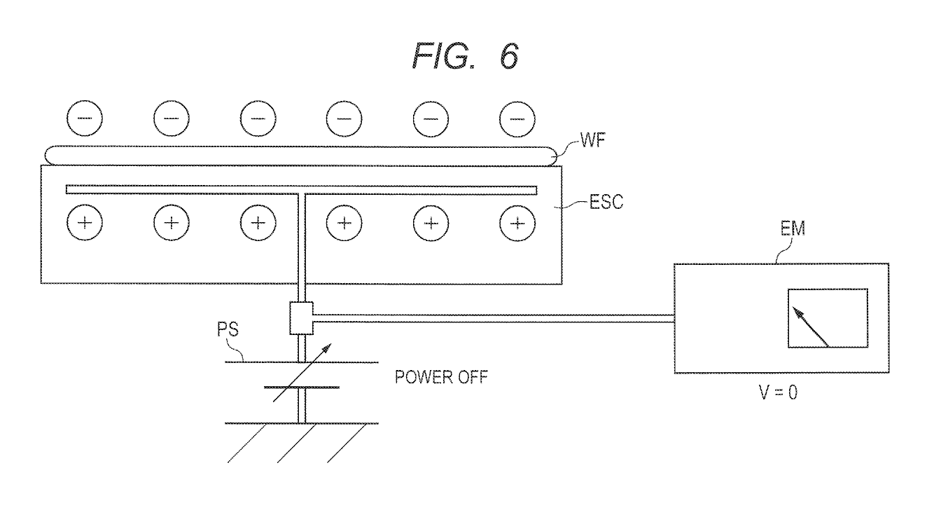

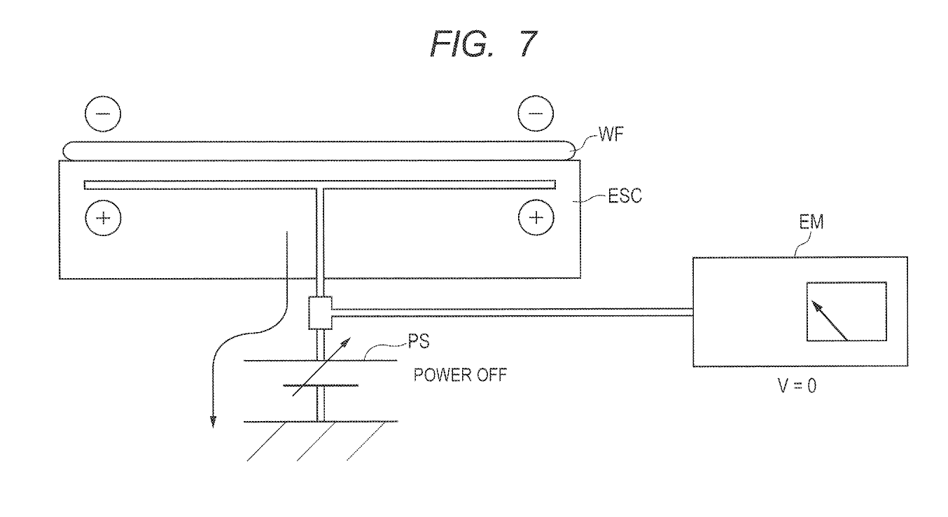

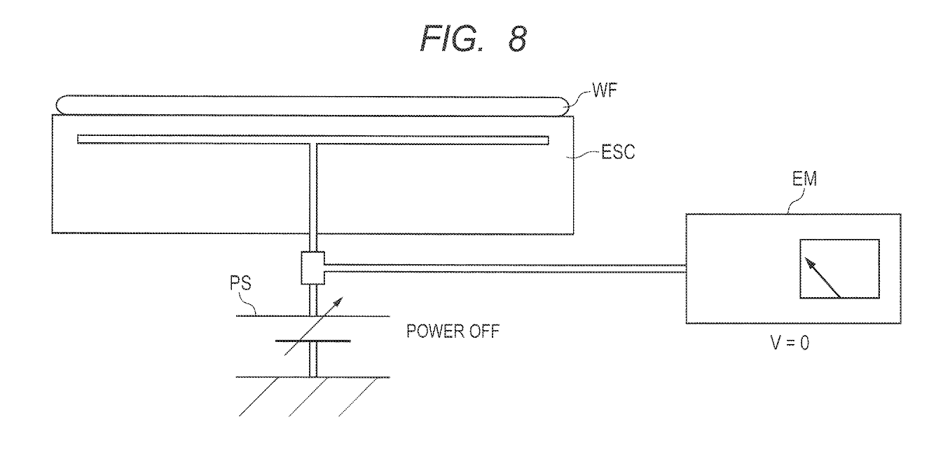

This will be hereinafter described. In FIG. 5, when the power source PS is turned on with the electrometer EM arranged between the electrostatic chuck ESC and the power source PS, the potential of the electrostatic chuck ESC becomes a power source potential (VDD) and the electrometer EM indicates the power source potential. Next, as shown in FIG. 6, when the power source PS is turned off, the electrostatic chuck ESC is coupled to the ground and the electrometer EM indicates the ground potential (0 V). Thereafter, when the plasma charge elimination processing is performed on the semiconductor wafer WF, for example, as shown in FIG. 7, the amount of the minus charges charged on the semiconductor wafer WF is decreased, while the plus charges generated in the electrostatic chuck ESC flow to the ground electrically coupled to the electrostatic chuck ESC for the amount of the electric charges corresponding to the minus charges eliminated from the semiconductor wafer WF. As the result, as shown in FIG. 7, the electrometer EM still indicates the ground potential (0 V). As shown in FIG. 8, also in the state in which the minus charges charged on the semiconductor wafer WF are all eliminated, the electrometer EM indicates the ground potential (0 V). In other words, even when the electrometer EM is simply set between the electrostatic chuck ESC and the power source PS to monitor the potential of the electrostatic chuck ESC, the electrometer EM indicates the ground potential (0 V) all in the case of starting the charge elimination of the minus charges charged on the semiconductor wafer WF with the power source PS turned off (FIG. 6), in the case of the midway state of the charge elimination (FIG. 7), and in the case of the finished state of the charge elimination (FIG. 8). According to this, even if simply arranging the electrometer EM between the electrostatic chuck ESC and the power source PS to monitor the potential of the electrostatic chuck ESC, it is still difficult to determine whether or not the charge elimination of the semiconductor wafer WF is finished.

The first embodiment makes a new device capable of accurately determining whether or not the charge elimination of a semiconductor wafer WF is finished, in the structure of monitoring the potential of the electrostatic chuck ESC with the electrometer EM arranged between the power source PS and the electrostatic chuck ESC. Hereinafter, a technical idea related to this device according to the first embodiment will be described referring to the drawings.

### <Structure of Semiconductor Manufacturing Device According to First Embodiment>

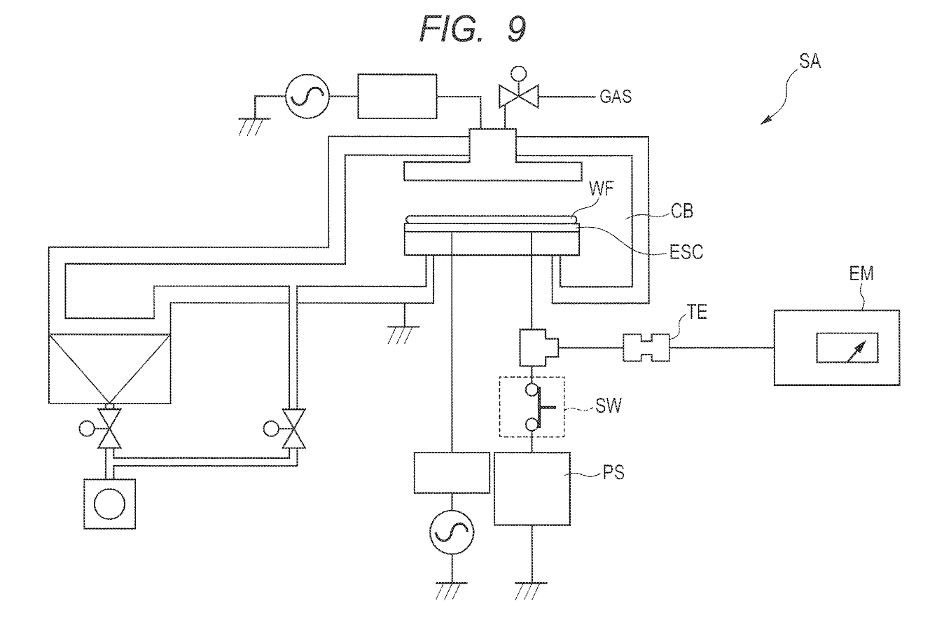

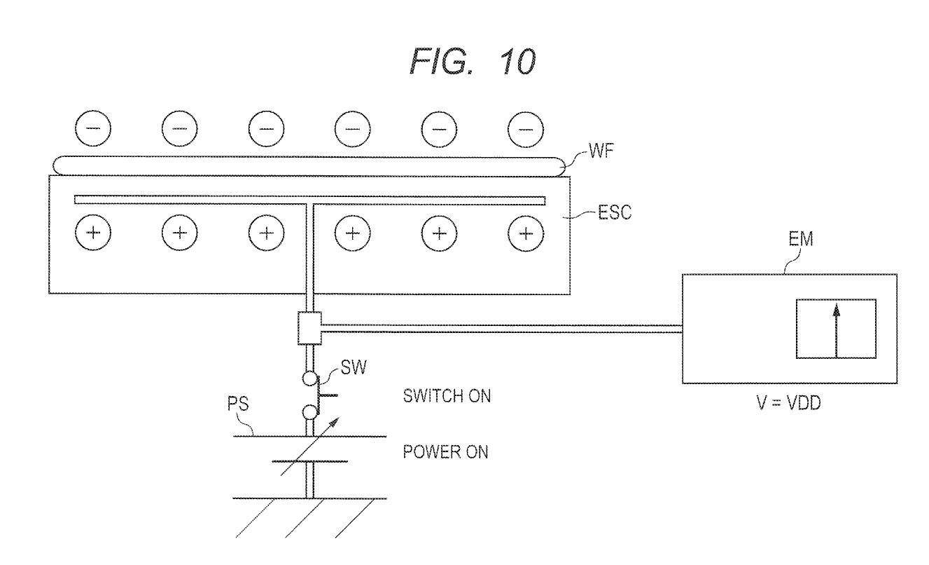

FIG. 9 is a view showing a schematic structure of a semiconductor manufacturing device SA according to a first embodiment. In FIG. 9, a main component element of the semiconductor manufacturing device SA according to the first embodiment will be described. As shown in FIG. 9, the semiconductor manufacturing device SA according to the first embodiment includes a chamber CB as a processing chamber for performing the processing on the semiconductor wafer WF. The chamber CB includes an electrostatic chuck ESC that can be electrically coupled to the power source (direct current power source) PS, and a semiconductor wafer WF is mounted on the electrostatic chuck ESC. Further, a switch SW for controlling the conduction or non-conduction between the electrostatic chuck ESC and the power source PS is provided between the electrostatic chuck ESC and the power source PS. Further, the semiconductor manufacturing device SA includes a terminal TE that can be coupled to an external device, and the terminal TE is electrically coupled to the electrostatic chuck ESC. For example, as shown in FIG. 9, being coupled to the terminal TE, the electrometer EM is designed to be able to monitor the potential of the electrostatic chuck ESC.

### <Operation of Semiconductor Manufacturing Device>

The semiconductor manufacturing device according to the first embodiment is configured as mentioned above and the operation of the semiconductor manufacturing device will be hereinafter described.

### «Adsorption Operation of Semiconductor Wafer by Electrostatic Chuck»

At first, an adsorption operation of the semiconductor wafer WF by the electrostatic chuck ESC provided in the semiconductor manufacturing device SA will be described referring to the drawings.

After the semiconductor wafer WF is mounted on the electrostatic chuck ESC, the switch SW is turned on, to electrically couple the electrostatic chuck ESC to the power source PS and to turn on the power source PS. According to this, the electrostatic chuck ESC receives the power source potential (VDD) from the power source PS and is charged with the plus charges. As the result, the semiconductor wafer WF arranged on the electrostatic chuck ESC attracts the minus charges and is electrified. Therefore, electrostatic attraction works between the electrostatic chuck ESC and the semiconductor wafer WF and the semiconductor wafer WF is adsorbed by the electrostatic chuck ESC fixedly. Here, the electrometer EM monitors the potential of the electrostatic chuck ESC, and as the result, the electrometer EM indicates the power source potential (VDD). According to this, in the semiconductor manufacturing device according to the first embodiment, by turning on the power source PS and closing the switch SW, the power source PS and the electrostatic chuck ESC are made conductive, to make the electrostatic chuck ESC adsorb the semiconductor wafer WF.

### «Processing in Semiconductor Manufacturing Device»

After the semiconductor wafer WF is adsorbed by the electrostatic chuck ESC, processing is performed on the semiconductor wafer WF. Specifically, the semiconductor manufacturing device SA is formed by, for example, a dry etching device, a plasma Chemical Vapor Deposition (CVD) device, or a sputtering device, and various processing is performed depending on the type of the semiconductor manufacturing device SA. When the semiconductor manufacturing device SA is a dry etching device (plasma etching device), dry etching processing is performed on the semiconductor wafer WF adsorbed by the electrostatic chuck ESC. When the semiconductor manufacturing device SA is a plasma CVD device, film formation is performed according to the CVD method on the semiconductor wafer WF adsorbed by the electrostatic chuck ESC. When the semiconductor manufacturing device SA is a sputtering device, film formation is performed according to the sputtering method on the semiconductor wafer WF adsorbed by the electrostatic chuck ESC.

«Separation Operation of Semiconductor Wafer from Electrostatic Chuck»

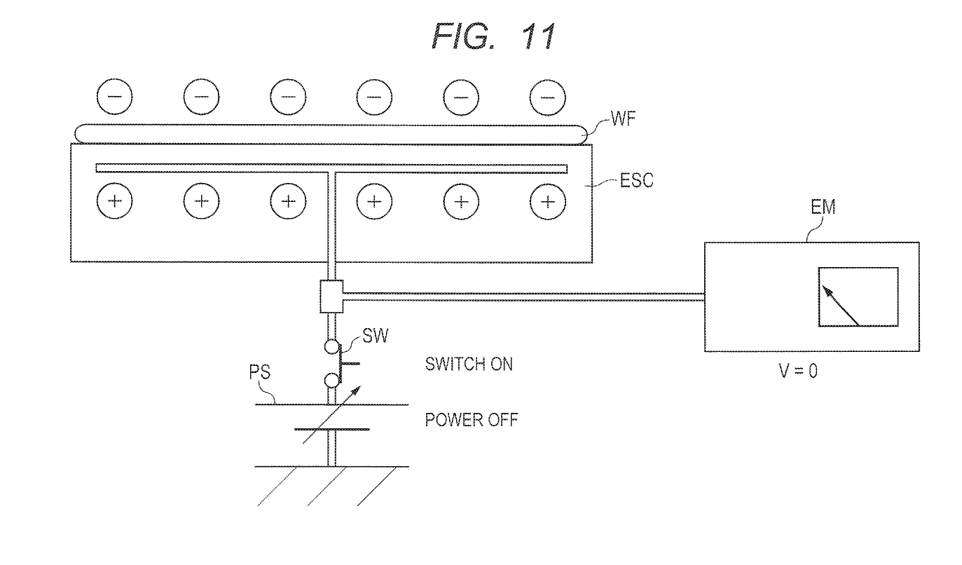

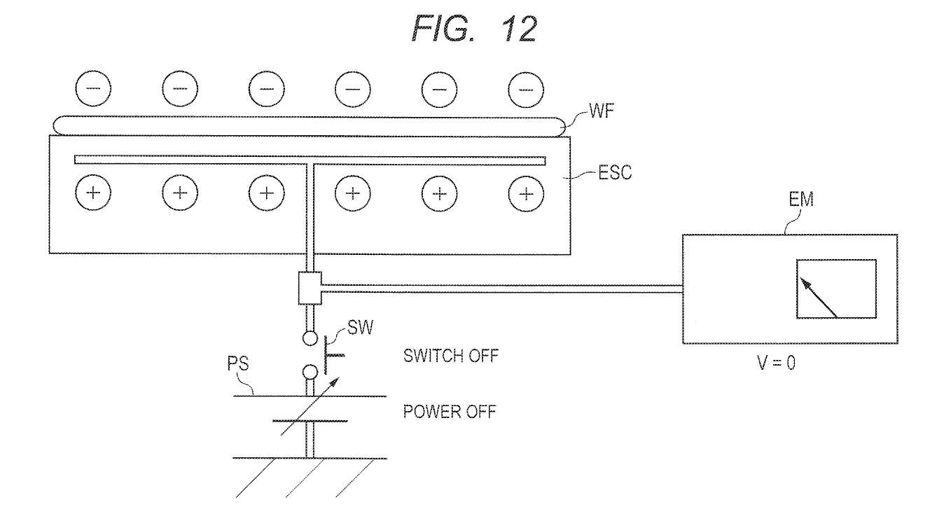

When the processing is finished in the semiconductor manufacturing device SA, the semiconductor wafer WF is separated from the electrostatic chuck ESC in order to carry out the semiconductor wafer WF from the semiconductor manufacturing device SA. Hereinafter, the detail will be described. At first, as shown in FIG. 11, after finishing the processing on the semiconductor wafer WF, the power source PS is turned off. When the power source PS is turned off, the electrostatic chuck ESC is electrically coupled to the ground. As the result, the electrometer EM indicates the ground potential (0 V). Thereafter, as shown in FIG. 12, the switch SW is released, to make the power source PS and the electrostatic chuck ESC non-conductive. By releasing the switch SW, the electrostatic chuck ESC is electrically separated from the ground, into a floating state. The electrometer EM keeps the state of indicating the ground potential (0 V).

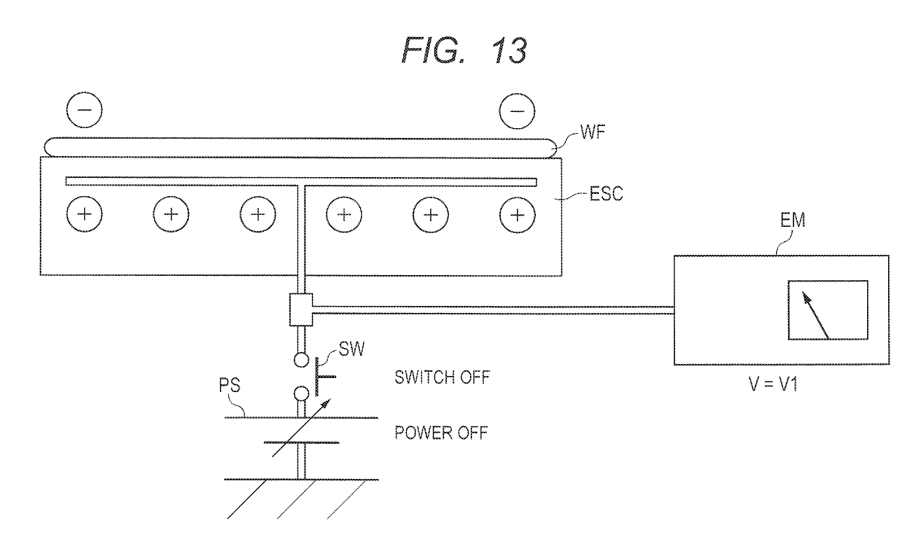

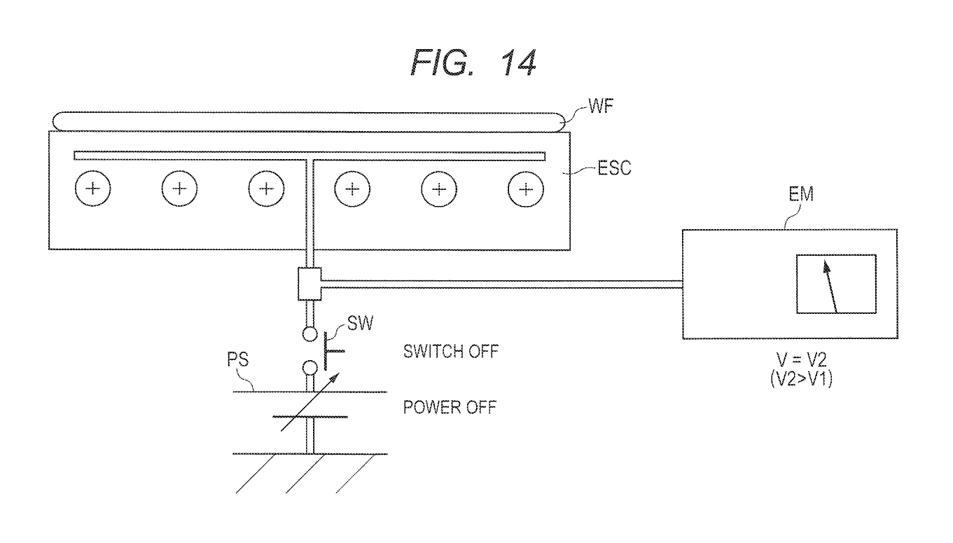

Then, the charge elimination processing, for example, typified by the plasma charge elimination processing is performed on the semiconductor wafer WF mounted on the electrostatic chuck ESC. According to this, the minus charges charged on the semiconductor wafer WF are eliminated. Particularly, FIG. 13 schematically shows the midway state of eliminating the minus charges charged on the semiconductor wafer WF. For example, while the minus charges charged on the semiconductor wafer WF are getting less, the electrostatic chuck ESC is in a floating state, keeping the plus charges. As the result, relatively, the potential of the electrostatic chuck ESC rises and the electrometer EM varies to the potential V1 (V1>0). As shown in FIG. 14, when the charge elimination processing is further performed, the minus charges charged on the semiconductor wafer WF are completely eliminated. On the other hand, the electrostatic chuck ESC is in a floating state and keeps the plus charges. As the result, relatively the potential of the electrostatic chuck ESC further rises and the electrometer EM varies to the potential V2 (V2>V1). Thereafter, no minus charge is left in the semiconductor wafer WF, and therefore, the electrometer EM continuously indicates a constant value with the potential V2. In the first embodiment, according to the advance of the charge elimination processing of the minus charges charged on the semiconductor wafer WF, the potential indicated by the electrometer EM rises and thereafter, when the charge elimination processing of the semiconductor wafer WF is finished, the potential indicated by the electrometer EM takes a constant value.

As mentioned above, in the first embodiment, the electrometer EM monitors the potential of the electrostatic chuck ESC, starting from the adsorption starting state of the semiconductor wafer WF by the electrostatic chuck ESC to the adsorption finishing state thereof. In the first embodiment, when the electrometer EM monitors the potential of the electrostatic chuck ESC and the potential of the electrostatic chuck ESC takes a constant value (it is within a predetermined range), the charge elimination processing of the semiconductor wafer WF is completely finished and the semiconductor wafer WF can be determined to be in the adsorption finishing state. According to this, the first embodiment can avoid the forcedly separation of the semiconductor wafer WF from the electrostatic chuck ESC in the insufficient state of the charge elimination. In other words, the first embodiment can accurately determine whether or not the charge elimination of the semiconductor wafer WF is finished; as the result, after the completion of the charge elimination processing on the semiconductor wafer WF, the semiconductor wafer WF can be separated from the electrostatic chuck ESC, hence to effectively avoid cracking of the semiconductor wafer WF.

### <Characteristic in First Embodiment>

Next, characteristic in the first embodiment will be described. A characteristic point in the first embodiment is the structure of providing the switch SW between the electrostatic chuck ESC and the power source PS, for example, as shown in FIG. 9, as a prerequisite. According to the characteristic point in the first embodiment, for example, as shown in FIGS. 11 to 14, when performing the charge elimination processing on the semiconductor wafer WF adsorbed by the electrostatic chuck ESC, the switch SW is released and the electrostatic chuck ESC is turned in a floating state, hence to monitor the potential of the electrostatic chuck ESC. According to this, the first embodiment can accurately determine whether or not the charge elimination of the semiconductor wafer WF is finished.

This point will be described in below. For example, as shown in FIG. 10, in the state in which the electrostatic chuck ESC adsorbs the semiconductor wafer WF, the electrostatic chuck ESC is charged with the plus charges, while the semiconductor wafer WF is charged with the minus charges. Therefore, the electrostatic attraction working between the plus charges in the electrostatic chuck ESC and the minus charges in the semiconductor wafer WF can fix the semiconductor wafer WF to the electrostatic chuck ESC assuredly. After processing is performed on the semiconductor wafer WF, it is necessary to separate the semiconductor wafer WF from the electrostatic chuck ESC. In order to cancel the electrostatic attraction generated between the electrostatic chuck ESC and the semiconductor wafer WF, the charge elimination processing is performed to eliminate the minus charges induced to the semiconductor wafer WF.

In the first embodiment, for example, as shown in FIG. 12, the electrostatic chuck ESC is separated from the ground, into a floating state. Here, when the charge elimination processing is performed on the semiconductor wafer WF, the minus charges induced to the semiconductor wafer WF is getting less according to the advance of the charge elimination processing. When the electrostatic chuck ESC is in a floating state, the plus charges induced to the electrostatic chuck ESC cannot run away to the ground and therefore, the plus charges induced to the electrostatic chuck ESC are kept as they are. In the first embodiment, according to the advance of the charge elimination processing, a difference between the plus charge and the minus charge becomes larger and the potential of the electrostatic chuck ESC rises in a plus direction. In short, with the electrostatic chuck ESC in a floating state, when the charge elimination processing is performed on the semiconductor wafer WF, the potential of the electrostatic chuck ESC varies. After the minus charges induced to the semiconductor wafer WF are completely eliminated, a difference between the plus charge and the minus charge does not vary. This means that after finishing the charge elimination processing on the semiconductor wafer WF, the potential of the electrostatic chuck ESC becomes constant. During the charge elimination processing performed on the semiconductor wafer WF, when the potential of the electrostatic chuck ESC is monitored with the electrostatic chuck ESC in a floating state, the potential of the electrostatic chuck ESC varies in a plus direction; upon the completion of the charge elimination processing, the potential of the electrostatic chuck ESC becomes constant. In other words, it is possible to recognize the completion of the charge elimination processing on the semiconductor wafer WF by detecting that the potential of the electrostatic chuck ESC becomes constant. According to the characteristic point in the first embodiment, it is possible to accurately determine whether or not the charge elimination of the semiconductor wafer WF is finished. As the result, according to the first embodiment, it is possible to avoid the forcedly separation of the semiconductor wafer WF from the electrostatic chuck ESC in the insufficient state of the charge elimination. According to the characteristic point in the first embodiment, whether or not the charge elimination of the semiconductor wafer WF is finished can be accurately determined, and therefore, after the charge elimination processing is completely finished on semiconductor wafer WF, the semiconductor wafer WF can be separated from the electrostatic chuck ESC. According to the characteristic point in the first embodiment, it is possible to effectively avoid the cracking of the semiconductor wafer WF.

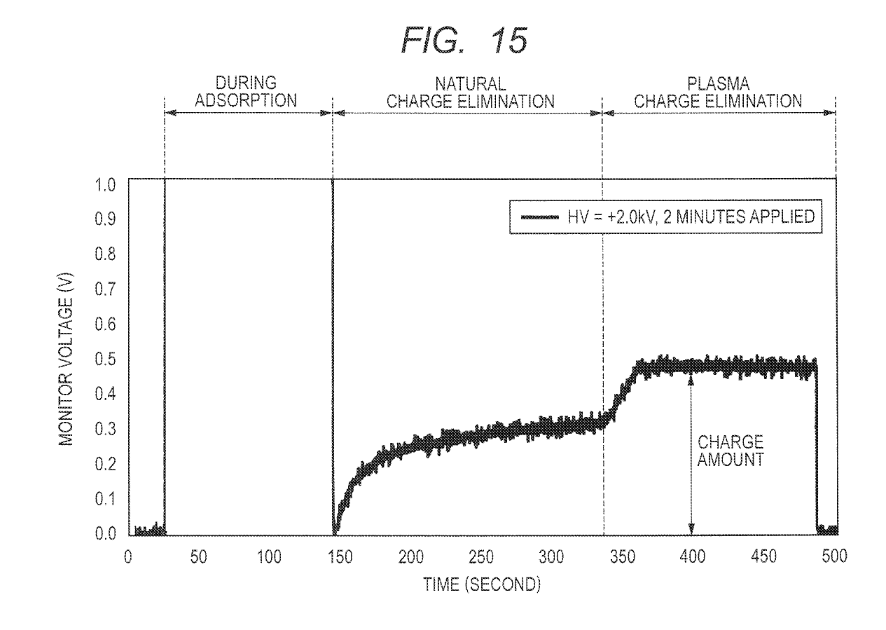

FIG. 15 is a view showing one example of the waveform obtained when the electrometer EM monitors the potential of the electrostatic chuck ESC. In FIG. 15, a vertical axis indicates a monitor voltage of the electrometer EM monitoring the potential of the electrostatic chuck ESC and a horizontal axis indicates time (second). As shown in FIG. 15, the range of “during adsorption” corresponds to the state in which the electrostatic chuck ESC is adsorbing the semiconductor wafer WF with both the power source PS and the switch SW turned on, and the monitor voltage becomes the power source voltage (VDD). Next, the range of “natural charge elimination” corresponds to the state in which the charge elimination processing is not positively performed with both the power source PS and the switch SW turned off and with the electrostatic chuck ESC in a floating state. In this case, the minus charges changed on the semiconductor wafer WF decrease more than a little by the natural charge elimination. As the result, the monitor voltage gradually rises from 0 V in a plus direction. Thereafter, the range of the “plasma charge elimination” corresponds to the state in which the plasma charge elimination processing is positively performed on the semiconductor wafer WF. In this range, the inclined waveform corresponds to the state of decreasing the minus charges charged on the semiconductor wafer WF according to the plasma charge elimination processing and the flat waveform thereafter indicates the state in which the minus charges charged on the semiconductor wafer WF are completely eliminated according to the plasma charge elimination processing. The arriving voltage when the monitor voltage becomes constant corresponds to the electric charge amount charged on the semiconductor wafer WF. Hereinafter, this will be described.

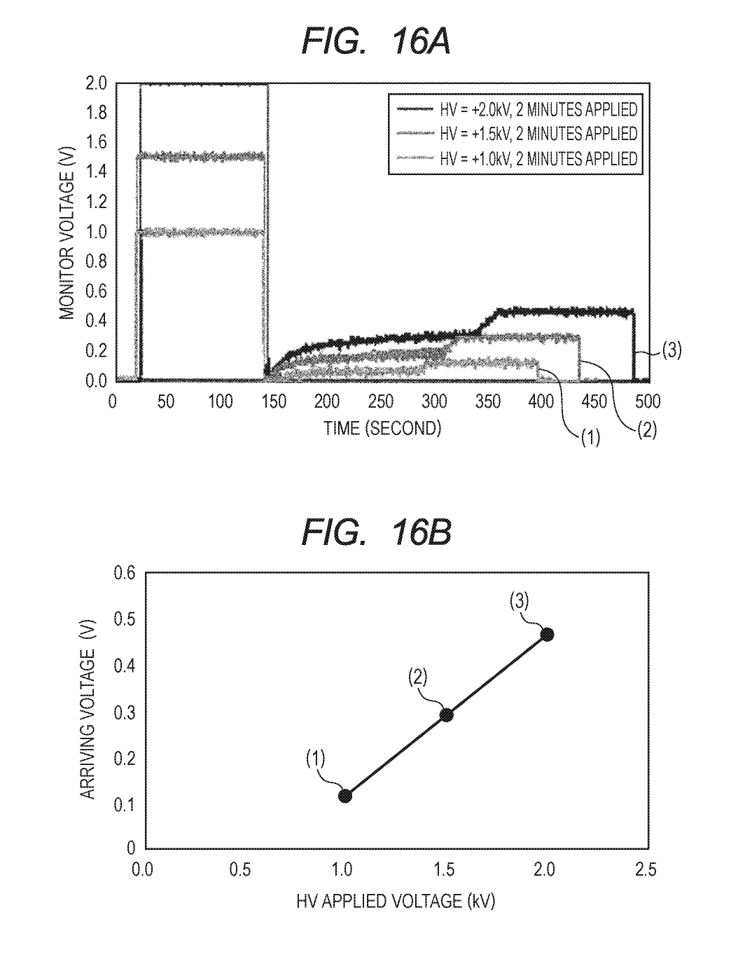

In FIG. 16A, a waveform (1) indicates the waveform when the power source voltage of the power source PS is defined as +1.0 kV and the same voltage is applied to the electrostatic chuck ESC only for two minutes, and a waveform (2) indicates the waveform when the power source voltage of the power source PS is defined as +1.5 kV and the same voltage is applied to the electrostatic chuck ESC only for two minutes. A waveform (3) indicates the waveform when the power source voltage of the power source PS is defined as +2.0 kV and the same voltage is applied to the electrostatic chuck ESC only for two minutes.

From FIG. 16A, it is found that according as the power source voltage of the power source PS is increased, the arriving voltage when the monitor voltage becomes constant gets larger. With respect to this point, for example, the structure including the electrostatic chuck ESC and the semiconductor wafer WF is regarded as a capacitor . In this case, when the electric charge amount is defined as “Q”, the capacitance value is defined as “C”, and the voltage is defined as “V”, there is a relation of “Q=C×V”. In short, based on this relational expression, the electric charge amount “Q” and the voltage “V” are in a proportional relationship. In FIG. 16B, when a relation between the power voltage (HV-applied voltage) (corresponding to “V”) of the power source PS and the arriving voltage is plotted, it is found that they are in a proportional relationship. Accordingly, it is found that the arriving voltage is a parameter corresponding to the electric charge amount “Q”, or the charged amount charged on the semiconductor wafer WF. That the monitor voltage becomes constant (arriving voltage) means no variation in the charged amount. No variation in the charged amount means that the minus charges charged on the semiconductor wafer WF are all eliminated with no more charge, and in other words, that the plasma charge elimination processing is finished. In the first embodiment, when the monitor voltage becomes constant, it is proper to determine that the charge elimination processing is finished, which is ensured from the results of FIGS. 16A and 16B.

The basic idea of the first embodiment is to adopt the structure capable of distinguishing the midway state of the charge elimination processing of the semiconductor wafer WF and the finished state thereof. This is because if the midway state of the charge elimination processing of the semiconductor wafer WF can be distinguished from the finished state thereof, whether the charge elimination processing on the semiconductor wafer WF is finished or not can be accurately determined. In the first embodiment, the above mentioned basic idea is embodied by the structure of performing the charge elimination processing on the semiconductor wafer WF while making the electrostatic chuck ESC in a floating state. According to this structure, when the potential of the electrostatic chuck ESC is monitored with the electrostatic chuck ESC in a floating state, the potential of the electrostatic chuck ESC in the midway state of the charge elimination processing varies in a plus direction and the potential of the electrostatic chuck ESC in the finished state of the charge elimination processing becomes constant. In short, by monitoring the potential of the electrostatic chuck ESC with the same chuck in a floating state, the midway state of the charge elimination processing and the finished state thereof can be distinguished according to the potential of the electrostatic chuck ESC. As the next stage, in the first embodiment, automation processing by a computer is realized to distinguish the midway state and the finished state of the charge elimination processing by monitoring the potential of the electrostatic chuck ESC with the electrostatic chuck ESC in a floating state.

### <Automation Processing by Computer>

Hereinafter, the automation processing by a computer will be described. In the first embodiment, a device for realizing the distinction of the midway state and the finished state of the charge elimination processing by monitoring the potential of the electrostatic chuck ESC with the same in a floating state, in the automation processing by a computer, is referred to as a charge elimination evaluating device.

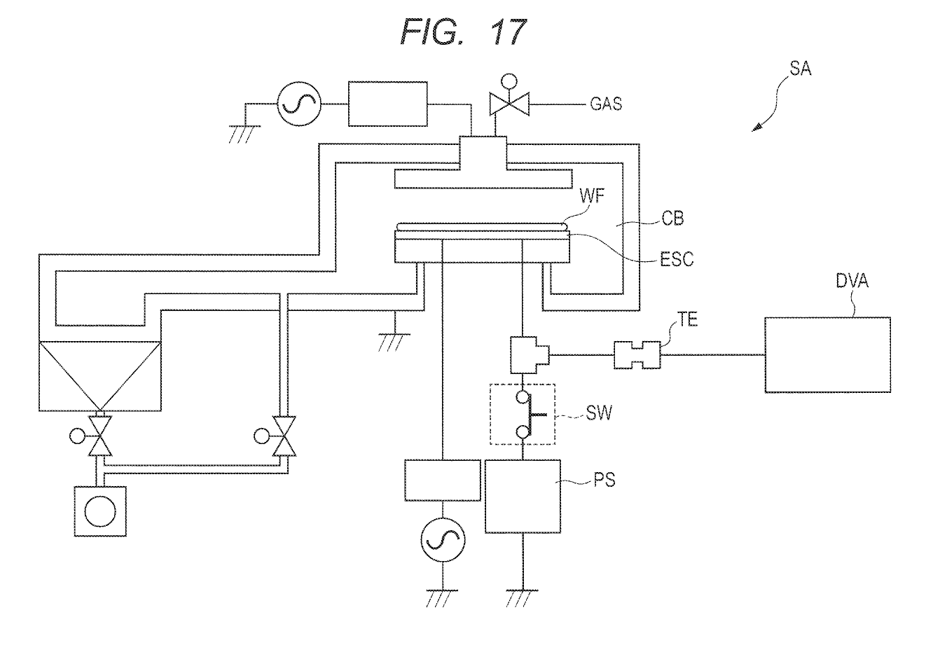

FIG. 17 is a view showing one example of a structure for coupling the semiconductor manufacturing device SA according to the first embodiment and a charge elimination evaluating device DVA according to the first embodiment. In FIG. 17, the semiconductor manufacturing device SA according to the first embodiment includes a terminal (external connection terminal) TE provided between the electrostatic chuck ESC and the switch SW. Here, the terminal (external connection terminal) TE is provided outside the semiconductor manufacturing device SA and coupled to the charge elimination evaluating device DVA working as a monitor for monitoring the potential of the electrostatic chuck ESC from the adsorption starting state of the semiconductor wafer WF to the adsorption finishing state thereof by the electrostatic chuck ESC. In the first embodiment, for example, as shown in FIG. 17, although the structural example of providing the charge elimination evaluating device DVA outside the semiconductor manufacturing device SA has been described, the technical idea of the first embodiment is not restricted to this but the charge elimination evaluating device DVA may be built in within the semiconductor manufacturing device SA. Specifically, the semiconductor manufacturing device SA may have a monitor (charge elimination evaluating device) for monitoring the potential of the electrostatic chuck ESC from the adsorption starting state of the semiconductor wafer WF to the adsorption finishing state and this monitor may be provided between the electrostatic chuck ESC and the switch SW.

### «Hardware Structure of Charge Elimination Evaluating Device»

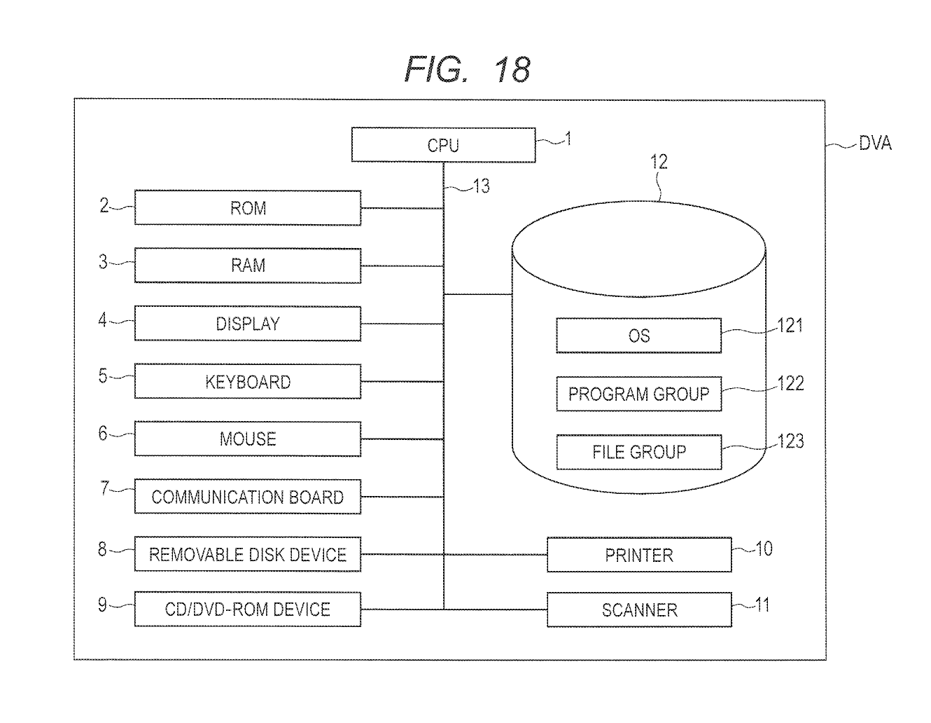

Hereinafter, at first, a hardware structure of the charge elimination evaluating device DVA according to the first embodiment will be described. FIG. 18 is a view showing one example of a hardware structure of the charge elimination evaluating device DVA according to the first embodiment. The structure shown in FIG. 18 is only one example of the hardware structure of the charge elimination evaluating device DVA and the structure thereof is not restricted to the above shown in FIG. 18 but may be another structure.

In FIG. 18, the charge elimination evaluating device DVA according to the first embodiment includes a Central Processing Unit (CPU) 1 for executing a program. This CPU 1 is electrically coupled to, for example, Read Only Memory (ROM) 2, Random Access Memory (RAM) 3, and a hard disk device 12 through a bus 13, to control these hardware devices.

Further, the CPU 1 is also coupled to an input device and an output device through the bus 13. As one example of the input device, there are a keyboard 5, a mouse 6, a communication board 7, and a scanner 11. On the other hand, as one example of the output device, there are a display 4, a communication board 7, and a printer 10. Further, the CPU 1 may be coupled to, for example, a removable disk device 8 and a CD/DVD-ROM device 9.

The charge elimination evaluating device DVA may be coupled to, for example, a network. For example, when the charge elimination evaluating device DVA is coupled to another external device through the network, the communication board 7 forming a part of the charge elimination evaluating device DVA is coupled to a local area network (LAN), a wide area network (WAN), and the Internet.

The RAM 3 is one example of the volatile memory, and the recording medium of the ROM 2, the removable disk device 8, CD/DVD-ROM device 9, and the hard disk device 12 is one example of the nonvolatile memory. These volatile and nonvolatile memories form the recording device of the charge elimination evaluating device DVA.

The hard disk device 12 stores, for example, an operating system (OS) 121, a program group 122, and a file group 123. Programs included in the program group 122 are executed by the CPU 1 using the operating system 121. Further, the RAM 3 stores at least a part of the program of the operating system 121 and the application program executed by the CPU 1, together with various types of data necessary for the processing by the CPU 1.

The ROM 2 stores a Basic Input Output System (BIOS) program and the hard disk device 12 stores a boot program. At the staring time of the charge elimination evaluating device DVA, the BIOS program stored in the ROM 2 and the boot program stored in the hard disk device 12 are executed, and the BIOS program and the boot program activate the operating system 121.

The program group 122 includes a program for realizing the function of the charge elimination evaluating device DVA, and this program is read and executed by the CPU 1. Further, the file group 123 stores information, data, signal values, variable values indicating the results of the processing by the CPU 1 as each file item.

The files are stored in the recording medium such as the hard disk device 12 and a memory. The information, data, signal values, variable values, and parameters stored in the recording medium such as the hard disk device 12 and the memory are read by the CPU 1 into a main memory and a cache memory, and used for the operation by the CPU 1 such as extraction, search, reference, comparison, calculation, processing, edit, output, print, and display. For example, during the above mentioned operation of the CPU 1, the information, data, signal values, variable values, and parameters are primarily stored in the main memory, register, cache memory, and buffer memory.

The function of the charge elimination evaluating device DVA may be realized by firmware stored in the ROM 2, or by only the software, by only the hardware typified by element, device, substrate, and wiring, by the combination of the software and the hardware, or the combination with the firmware. The firmware and the software are stored in the recording medium typified by the hard disk device 12, removable disk, CD-ROM, and DVD-ROM, as a program. The above program is read and executed by the CPU 1. In short, the program is to work the computer as the charge elimination evaluating device DVA.

As mentioned above, the charge elimination evaluating device DVA in the first embodiment is a computer including the CPU 1 as a processor, the hard disk device 12 and memory as the recording device, the keyboard, mouse, and communication board as the input device, the display, printer, and communication board as the output device. Each function of the charge elimination evaluating device DVA is realized by using the above mentioned processor, recording device, input device, and output device.

### «Functional Structure of Charge Elimination Evaluating Device»

Continuously, the functional structure of the charge elimination evaluating device DVA according to the first embodiment will be described.

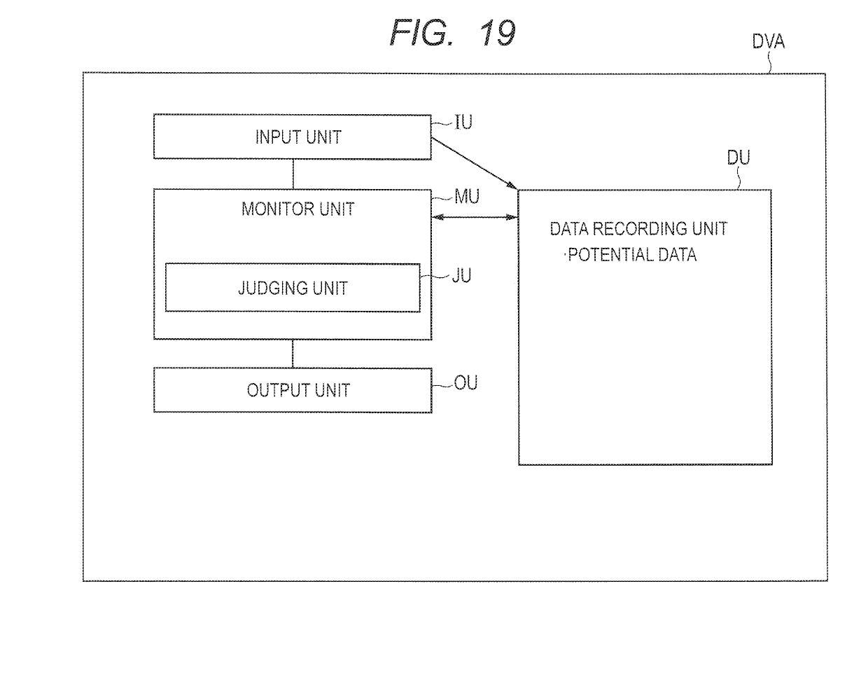

FIG. 19 is a view showing a functional block structure of the charge elimination evaluating device DVA according to the first embodiment. In FIG. 19, the charge elimination evaluating device DVA according to the first embodiment includes an input unit IU, a monitor unit MU, a judging unit JU, an output unit OU, a data recording unit DU.

The input unit IU is formed between the electrostatic chuck ESC and the switch SW in a connectable way (for example, can be coupled to a terminal (external connection terminal) TE provided in the semiconductor manufacturing device SA), to enter the potential data corresponding to the potential of the electrostatic chuck ESC; and the potential data entered from the input unit IU to the charge elimination evaluating device DVA is stored in the data recording unit DU.

In the first embodiment, the reason why the input data entered to the input unit IU is defined as the “potential data” not the “potential of the electrostatic chuck ESC” is because of the definite intention of showing that the input data includes not only the “potential of the electrostatic chuck ESC” itself but also the parameters corresponding to the “potential of the electrostatic chuck ESC”. In short, the “potential data” includes not only the “potential of the electrostatic chuck ESC” itself but also various parameters (data) corresponding to the “potential of the electrostatic chuck ESC”.

The monitor unit MU is designed to monitor the potential data (potential data entered to the input unit IU) stored in the data recording unit DU. Specifically, the monitor unit MU monitors the potential data entered from the input unit IU, during a period from the adsorption staring state of the semiconductor wafer WF by the electrostatic chuck ESC to the adsorption finishing state thereof.

The judging unit JU is designed to determine the semiconductor wafer WF to be in the adsorption finishing state when the potential data monitored by the monitor unit MU is within a predetermined range (when it gets constant in principle). As a concrete example, the judging unit JU can determine that the value of the potential data gets constant when a difference (difference data) between first potential data and second potential data sampled just before the first potential data is calculated and the difference is within a predetermined range.

The output unit OU is designed to output the result by the judging unit JU. Specifically, the output unit outputs the output data indicating that the semiconductor wafer WF arrives at the adsorption finishing state (separable state from the electrostatic chuck ESC) after finishing the charge elimination processing on the semiconductor wafer WF, to the semiconductor manufacturing device SA.

### «Charge Elimination Evaluating Method»

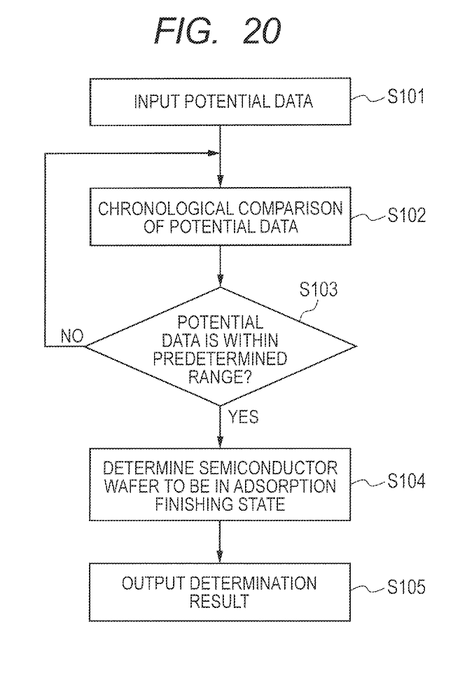

The charge elimination evaluating device DVA according to the first embodiment is configured as mentioned above, and hereinafter, a charge elimination evaluating method using the charge elimination evaluating device DVA will be described with reference to the drawings. FIG. 20 is a flow chart showing a flow of the charge elimination evaluating method according to the first embodiment. At first, in the charge elimination evaluating device DVA, the input unit IU inputs the potential data supplied from the terminal TE of the semiconductor manufacturing device SA (S101). Then, the monitor unit MU in the charge elimination evaluating device DVA monitors the potential data entered from the input unit IU to the charge elimination evaluating device DVA, during a period from the adsorption starting state of the semiconductor wafer WF by the electrostatic chuck ESC to the adsorption finishing state thereof. Specifically, the judging unit JU included in the monitor unit MU of the charge elimination evaluating device DVA determines whether or not several values of the latest potential data are within the predetermined range (S103), for example, by comparison of the values of the potential data sequentially entered (S102). When the values of the latest potential data are not within the predetermined range, the judging unit JU determines that the charge elimination processing of the semiconductor wafer WF is still on the way, and returning to S102, the comparison processing is repeated. On the other hand, when the values of the latest potential data are within the predetermined range, it determines that the semiconductor wafer WF arrives at the adsorption finishing state and creates the determination data indicating that the charge elimination processing has been finished (S104). The output unit OU in the charge elimination evaluating device DVA outputs the determination data (S105). Then, for example, upon receipt of the determination data from the output unit OU in the charge elimination evaluating device DVA, the semiconductor manufacturing device SA separates the semiconductor wafer WF from the electrostatic chuck ESC and carries out the semiconductor wafer WF outside. As mentioned above, the charge elimination evaluating method according to the first embodiment is realized.

### «Charge Elimination Evaluating Program»

The charge elimination evaluating method realized by the above mentioned charge elimination evaluating device DVA can be realized by a charge elimination processing program for executing the charge elimination evaluation processing in a computer. For example, in the charge elimination evaluating device DVA formed by a computer shown in FIG. 18, the charge elimination evaluating program according to the first embodiment can be introduced as one of the program group 122 stored in the hard disk device 12. By executing the charge elimination evaluating program in the computer as the charge elimination evaluating device DVA, the charge elimination evaluating method according to the first embodiment can be realized.

The charge elimination evaluating program for executing various processing for realizing the charge elimination evaluating method in the computer can be delivered with the same program stored in a computer readable recording medium. This recording medium includes, for example, magnetic recording medium such as hard disk and flexible disk, optical recording medium such as CD-ROM and DVD-ROM, and hardware device typified by nonvolatile memory such as ROM and EEPROM.

### Second Embodiment

Although in the first embodiment, an example of accurately grasping the finished state of the charge elimination processing on the semiconductor wafer WF has been described using the charge elimination evaluating device DVA, another using method of the charge elimination evaluating device DVA will be described in a second embodiment. For example, when the potential of the electrostatic chuck ESC is monitored with the above chuck in a floating state, the potential of the electrostatic chuck ESC in the midway state of the charge elimination processing varies in a plus direction and the potential of the electrostatic chuck ESC gets constant in the finished state of the charge elimination processing. The first embodiment has described the technical idea of grasping the finished state of the charge elimination processing by detecting the potential of the electrostatic chuck ESC getting constant by using the charge elimination evaluating device DVA. On the contrary, the second embodiment is to describe a technical idea for shortening the charge elimination processing time by detecting the potential of the electrostatic chuck ESC in the midway state of the charge elimination varying in a plus direction, using the charge elimination evaluating device DVA.

### <Functional Structure of Charge Elimination Evaluating Device>

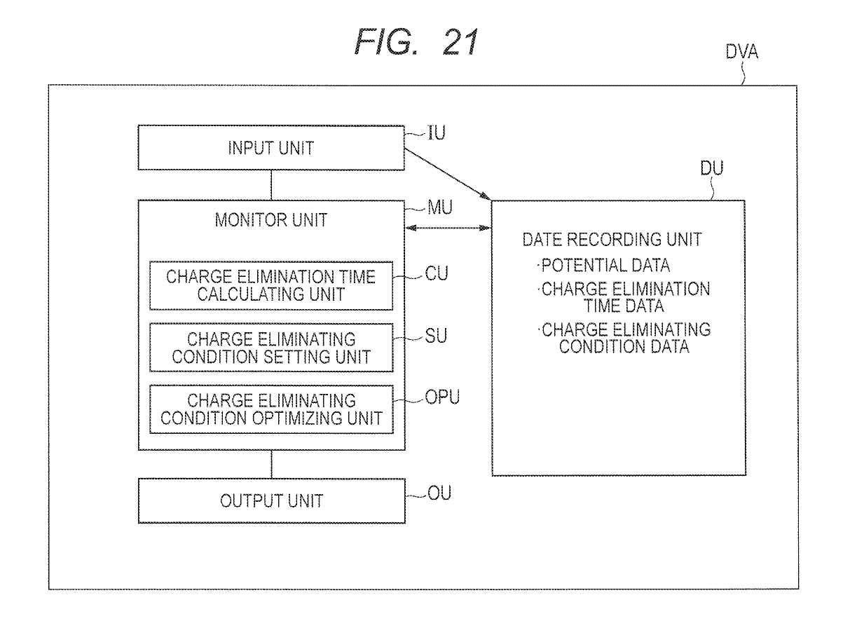

The functional structure of the charge elimination evaluating device DVA according to the second embodiment will be described. FIG. 21 is a view showing a functional block structure of a charge elimination evaluating device DVA according to the second embodiment. In FIG. 21, the charge elimination evaluating device DVA according to the second embodiment includes an input unit IU, a monitor unit MU, a charge elimination time calculating unit CU, a charge eliminating condition setting unit SU, a charge eliminating condition optimizing unit OPU, an output unit OU, and a data recording unit DU.

The input unit IU is formed between the electrostatic chuck ESC and the switch SW in a connectable way (for example, can be coupled to a terminal (external connection terminal) TE provided in the semiconductor manufacturing device SA), to enter the potential data corresponding to the potential of the electrostatic chuck ESC; and the potential data entered from the input unit IU to the charge elimination evaluating device DVA is stored in the data recording unit DU.

The monitor unit MU is designed to monitor the potential data (potential data entered into the input unit IU) stored in the data recording unit DU. Specifically, the monitor unit MU monitors the potential data entered from the input unit IU, during a period from the adsorption staring state of the semiconductor wafer WF by the electrostatic chuck ESC to the adsorption finishing state thereof.

The charge elimination time calculating unit CU is designed to specify the charge elimination time on the semiconductor wafer WF, based on a change of the potential of the electrostatic chuck ESC. Specifically, the charge elimination time calculating unit CU is designed to create the charge elimination time data by using the potential of the electrostatic chuck ESC in the midway state of the charge elimination processing changing in a plus direction and defining the changing time as the charge elimination time. Then, the charge elimination time data created by the charge elimination time calculating unit CU is stored in the data recording unit DU.

The charge eliminating condition setting unit SU is designed to set the charge eliminating condition data indicating the charge eliminating condition (for example, in the case of the plasma charge elimination processing, a chamber temperature, a gas pressure, a flow amount of gas) for performing the charge elimination processing on the semiconductor wafer WF in the semiconductor manufacturing device SA. This charge eliminating condition data is also stored in the data recording unit DU.

Based on the charge elimination time data calculated by the charge elimination time calculating unit CU, the charge eliminating condition optimizing unit OPU changes the charge eliminating condition data set by the charge eliminating condition setting unit SU and optimizes the charge eliminating condition to make the charge elimination time indicated by the charge elimination time data shortest.

The output unit OU outputs the charge eliminating condition data optimized by the charge eliminating condition optimizing unit OPU to the semiconductor manufacturing device SA.

### <Optimization Method of Charge Eliminating Condition>

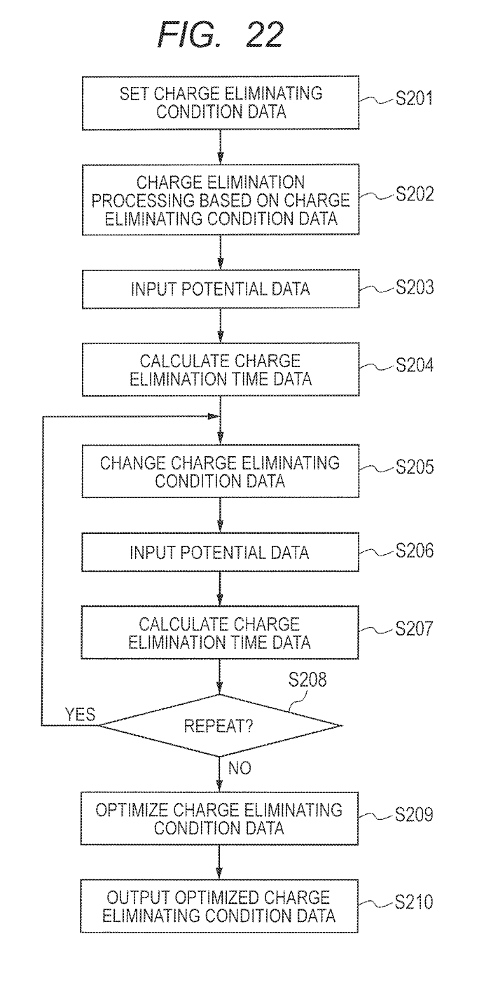

The charge elimination evaluating device DVA according to the second embodiment is configured as mentioned above, and hereinafter a method of optimizing a charge eliminating condition using the charge elimination evaluating device DVA will be described with reference to the drawings. FIG. 22 is a flowchart showing a flow of the above optimization method according to the second embodiment. At first, the charge elimination evaluating device DVA sets the charge eliminating condition data in the charge eliminating condition setting unit SU (S201). Then, the charge eliminating condition data is output by the output unit OU to the semiconductor manufacturing device SA and the semiconductor manufacturing device SA performs the charge elimination processing on the semiconductor wafer WF based on the charge eliminating condition data (S202). Thereafter, the potential data indicating the potential of the electrostatic chuck ESC within the semiconductor manufacturing device SA is input to the input unit IU in the charge elimination evaluating device DVA (S203). The charge elimination time calculating unit CU in the charge elimination evaluating device DVA calculates the charge elimination time data indicating the charge elimination time of the semiconductor wafer WF from the potential waveform based on the input potential data (S204). The charge eliminating condition optimizing unit OPU changes the charge eliminating condition data set in the charge eliminating condition setting unit SU (S205). The changed charge eliminating condition data is output from the output unit of the charge elimination evaluating device DVA to the semiconductor manufacturing device SA and the semiconductor manufacturing device SA performs the charge elimination processing on the next semiconductor wafer under the charge eliminating condition based on the changed charge eliminating condition data. Then, the potential data indicating the potential of the electrostatic chuck ESC in the semiconductor manufacturing device SA is input to the input unit IU in the charge elimination evaluating device DVA (S206). The charge elimination time calculating unit calculates the charge elimination time data indicating the charge elimination time of the semiconductor wafer WF from the potential waveform based on the input potential data (S207). Then, when the charge eliminating condition data is repeatedly changed, the operation is returned to Step S205 again, where the processing is repeated. On the other hand, when no more processing is repeated, the charge eliminating condition optimizing unit OPU in the charge elimination evaluating device DVA optimizes the charge eliminating condition data (S209). Specifically, by comparison of the plural charge elimination time data corresponding to the respective charge eliminating condition data, the charge eliminating condition data corresponding to the charge eliminating condition having the shortest charge elimination time is extracted as the optimum charge eliminating condition data. The optimum charge eliminating condition data is output from the output unit OU in the charge elimination evaluating device DVA to the semiconductor manufacturing device SA (S210). In this case, the semiconductor manufacturing device SA performs the charge elimination processing on the semiconductor wafer thereafter under the charge eliminating condition corresponding to the optimum charge eliminating condition data. As mentioned above, the optimization method of the charge eliminating condition according to the second embodiment is realized.

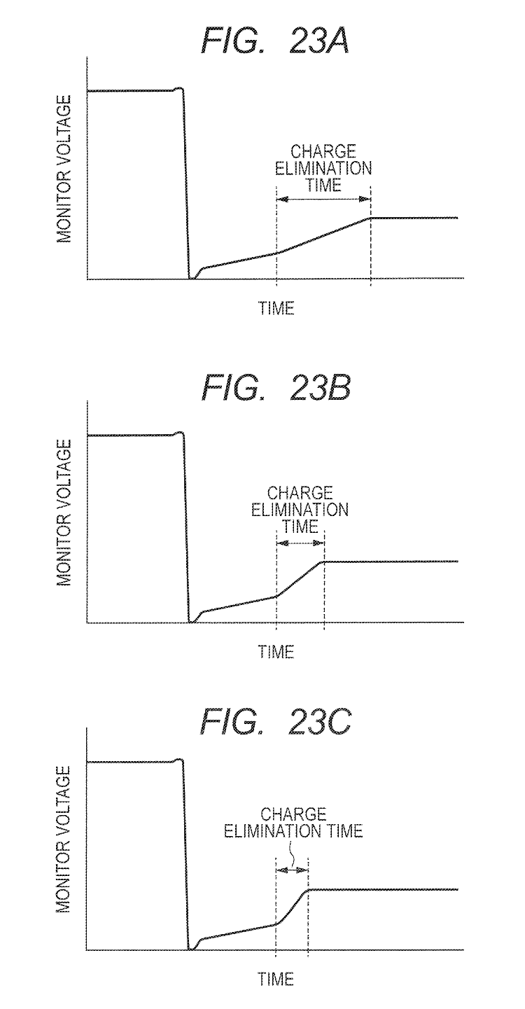

FIGS. 23A to 23C show voltage waveforms in the case of performing the charge elimination processing on the semiconductor wafer WF under various charge eliminating conditions. For example, FIG. 23A shows a voltage waveform under the charge eliminating condition A; FIG. 23B shows a voltage waveform under the charge eliminating condition B; and FIG. 23C shows a voltage waveform under the charge eliminating condition C. According to the optimization method of the charge eliminating condition in the second embodiment, of the charge eliminating conditions A to C, the charge eliminating condition C having the shortest charge elimination time is extracted as the optimum charge eliminating condition data, and the charge eliminating condition C is thereafter used for the charge elimination processing of the semiconductor wafer. As the result, according to the second embodiment, it is possible to shorten the charge elimination time in the charge elimination processing of the semiconductor wafer, hence to improve the throughput in the semiconductor manufacturing device SA.

### <Modified Example>

In this modified example, the charge elimination evaluating device DVA for adjusting the charge eliminating condition in the process of eliminating the electric charges charged on the semiconductor wafer will be described, based on the plural potential waveforms of the electrostatic chuck obtained by starting the processing of a plurality of semiconductor wafers WF.

### «Functional Structure of Charge Elimination Evaluating Device»

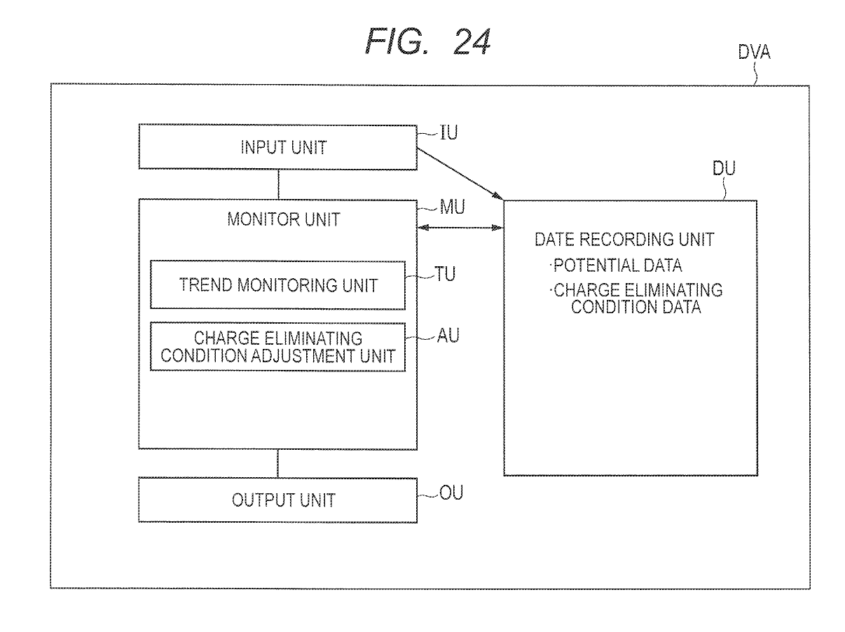

A functional structure of the charge elimination evaluating device DVA according to a modified example will be described. FIG. 24 is a view showing a functional block structure of the charge elimination evaluating device DVA according to the modified example. In FIG. 24, the charge elimination evaluating device DVA in the modified example includes an input unit IU, a monitor unit MU, a trend monitoring unit TU, a charge eliminating condition adjustment unit AU, an output unit U, and a data recording unit DU.

The input unit IU is formed between the electrostatic chuck ESC and the switch SW in a connectable way (for example, can be coupled to a terminal (external connection terminal) TE provided in the semiconductor manufacturing device SA), to enter the potential data corresponding to the potential of the electrostatic chuck ESC; and the potential data entered from the input unit IU to the charge elimination evaluating device DVA is stored in the data recording unit DU.

The monitor unit MU is designed to monitor the potential data (potential data entered to the input unit IU) stored in the data recording unit DU. Specifically, the monitor unit MU monitors the potential data entered from the input unit IU, during a period from the adsorption staring state of the semiconductor wafer WF by the electrostatic chuck ESC to the adsorption finishing state thereof.

The trend monitoring unit TU determines the trend of changing potential waveform, from the plural potential waveforms of the electrostatic chuck ESC obtained by starting the processing of the plural semiconductor wafers WF.

The charge eliminating condition adjustment unit AU adjusts the charge eliminating condition data indicating the charge eliminating condition, based on the trend of the changing potential waveform determined by the trend monitoring unit TU.

The output unit OU outputs the charge eliminating condition data adjusted by the charge eliminating condition adjustment unit AU to the semiconductor manufacturing device SA.

### «Adjustment Method of Charge Eliminating Condition»

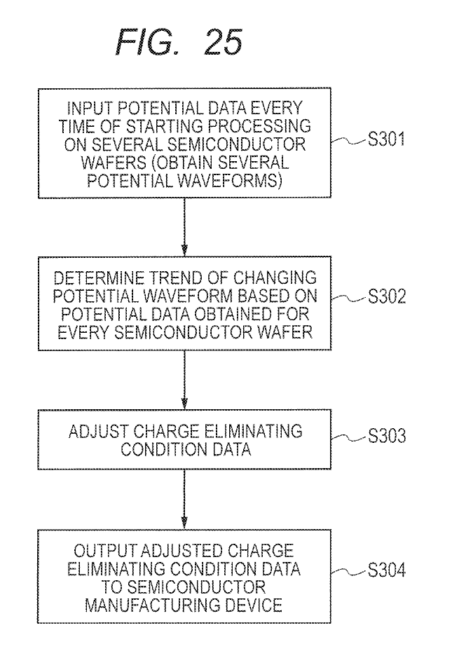

The charge elimination evaluating device DVA in the modified example is configured as mentioned above, and a method of adjusting the charge eliminating condition using this charge elimination evaluating device DVA will be hereinafter described with reference to the drawings. FIG. 25 is a flow chart showing a flow of the above adjustment method in the modified example. At first, the input unit IU in the charge elimination evaluating device DVA inputs the potential data indicating the potential of the electrostatic chuck ESC from the semiconductor manufacturing device SA every time of starting the processing of the semiconductor wafers WF (S301). According to this, the charge elimination evaluating device DVA obtains a plurality of potential waveforms. The trend monitoring unit TU in the charge elimination evaluating device DVA determines the trend of the changing potential waveform, based on the potential data (the plural potential waveforms) obtained for every semiconductor wafer WF (S302). For example, the trend monitoring unit TU reads a chronological change of the changing potential waveform from the plural potential waveforms and determines the trend of the changing potential waveform from this chronological change. Continuously, the charge eliminating condition adjustment unit AU in the charge elimination evaluating device DVA adjusts the charge eliminating condition data indicating the charge eliminating condition, based on the trend of the changing potential waveform determined by the trend monitoring unit TU (S303). For example, the charge eliminating condition adjustment unit AU adjusts the charge eliminating condition data to control the chronological change (chronological degradation) of the potential waveform. The output unit OU in the charge elimination evaluating device DVA outputs the charge eliminating condition data adjusted by the charge eliminating condition adjustment unit AU to the semiconductor manufacturing device SA (S304). In this case, the semiconductor manufacturing device SA thereafter performs the charge elimination processing on the semiconductor wafer under the charge eliminating condition corresponding to the adjusted charge eliminating condition data. According to the modified example, it is possible to forecast the cracking of the semiconductor wafer WF by monitoring the trend of the changing potential waveform and further to prevent the cracking of the semiconductor wafer WF by adjusting the charge eliminating condition data based on the trend of the changing potential waveform. As mentioned above, the adjustment method of the charge eliminating condition in the modified example can be realized.

### Third Embodiment

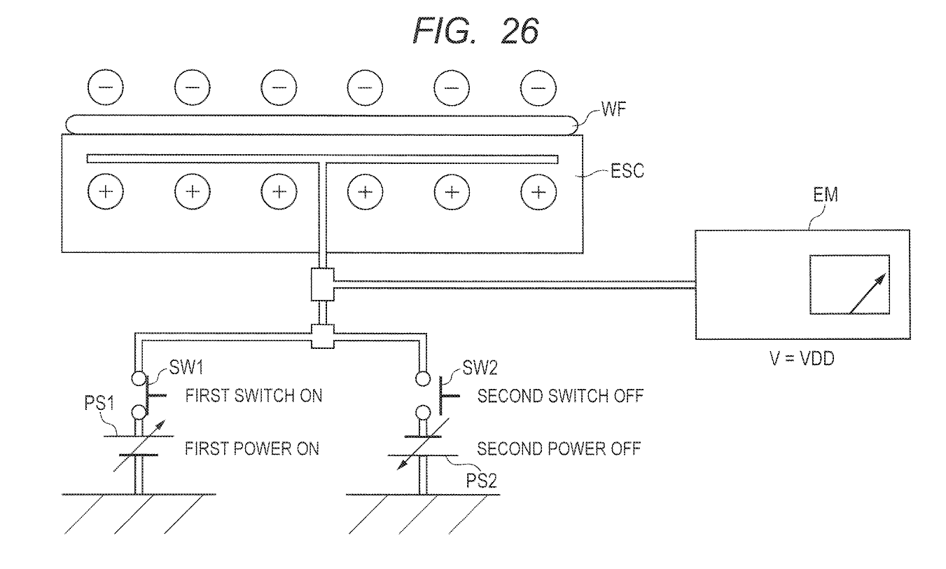

In a third embodiment, an example of adopting the technical idea to the structure of “charge elimination method with reverse voltage” will be described as a method of eliminating the minus charges charged on the semiconductor wafer WF. In this case, a semiconductor manufacturing device in the third embodiment includes, for example, a first power source PS1 electrically coupled to the electrostatic chuck ESC and a first switch SW1 for switching the conductivity and the non-conductivity between the power source PS1 and the electrostatic chuck ESC, as shown in FIG. 26. Further, the semiconductor manufacturing device in the third embodiment includes a second power source (reverse-voltage power source) PS2 electrically coupled to the electrostatic chuck ESC and having a reverse polarity to the power source PS1, and a second switch SW2 for switching the conductivity and the non-conductivity between the second power source PS2 and the electrostatic chuck ESC.

The semiconductor manufacturing device in the third embodiment is configured as mentioned above and an operation of the semiconductor manufacturing device will be hereinafter described.

### <Adsorption Operation of Semiconductor Wafer by Electrostatic Chuck>

At first, the adsorption operation of a semiconductor wafer WF by the electrostatic chuck ESC provided in the semiconductor manufacturing device will be described with reference to the drawings.

As shown in FIG. 26, after the semiconductor wafer WF is mounted on the electrostatic chuck ESC, the first switch SW1 is turned on, to electrically couple the electrostatic chuck ESC and the first power source PS1, and at the same time, the first power source PS1 is turned on. On the other hand, as shown in FIG. 26, the second switch SW2 is turned off, to cut off electricity between the electrostatic chuck ESC and the second power source PS2 and at the same time, the second power source PS2 is turned off . According to this, a power source potential (VDD) is supplied from the first power source PS1 to the electrostatic chuck ESC and the plus charges are accumulated in the electrostatic chuck ESC. As the result, the minus charges are induced to the semiconductor wafer WF arranged on the electrostatic chuck ESC and the semiconductor wafer WF is electrified. Therefore, electrostatic attraction works between the electrostatic chuck ESC and the semiconductor wafer WF and the semiconductor wafer WF is attracted and fixed to the electrostatic chuck ESC. As the result of monitoring the potential of the electrostatic chuck ESC, the electrometer EM indicates the power source potential (VDD). According to the semiconductor manufacturing device in the third embodiment, by turning on the first power source PS1 and closing the first switch SW1, the first power source PS1 and the electrostatic chuck ESC are made conductive, hence to enable the electrostatic chuck ESC to adsorb the semiconductor wafer WF.

<Separating Operation of Semiconductor Wafer From Electrostatic Chuck> (in the case of good charge elimination)

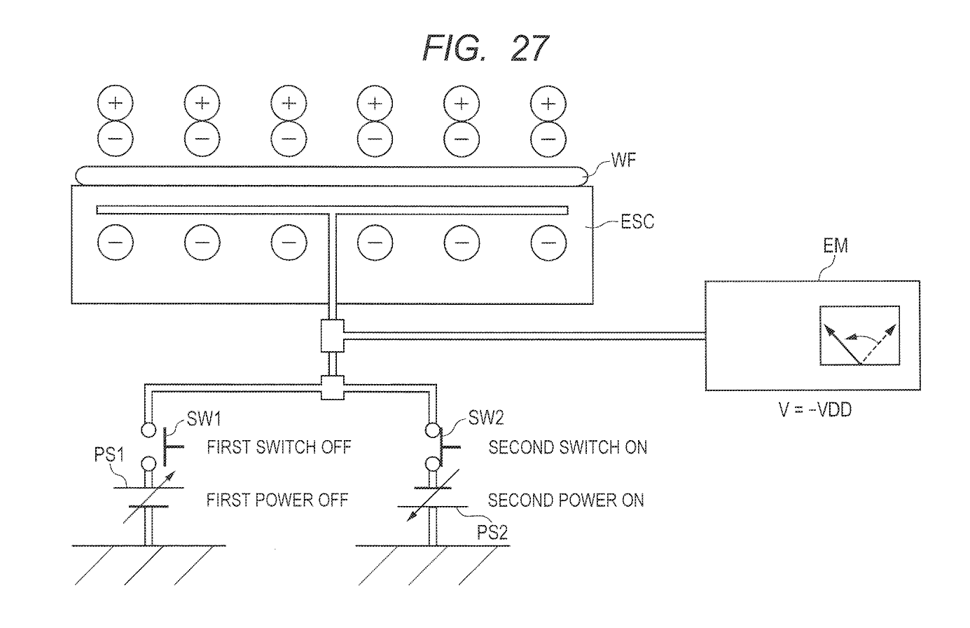

An operation of separating the semiconductor wafer WF from the electrostatic chuck ESC will be described. At first, as shown in FIG. 27, after finishing the processing on the semiconductor wafer WF, the first power source PS1 is turned off and the first switch SW1 is released, hence to make the first power source PS1 and the electrostatic chuck ESC non-conductive. Then, the second power source (reverse-voltage power source) PS2 is turned on and the second switch SW2 is closed, to make the second power source (reverse-voltage power source) PS2 and the electrostatic chuck ESC conductive, hence to eliminate the charges of the semiconductor wafer WF adsorbed by the electrostatic chuck ESC (“charge elimination with reverse voltage”). Specifically, as shown in FIG. 27, by turning on the second switch SW2, the electrostatic chuck ESC is electrically coupled to the second power source (reverse-voltage power source) PS2. As the result, the minus charges are induced to the electrostatic chuck ESC and the plus charges are induced to the semiconductor wafer WF. The semiconductor wafer WF has been already charged with the minus charges through the adsorption operation, and therefore, by the induction of the plus charges at this time caused by the electrical connection of the second power source (reverse-voltage power source) PS2 and the electrostatic chuck ESC, the minus charges and the plus charges are cancelled on the semiconductor wafer WF. As the result, the semiconductor wafer WF is neutralized; it is found that the electrical connection of the second power source (reverse-voltage power source) PS2 and the electrostatic chuck ESC leads to the “charge elimination with reverse voltage”. Here, as shown in FIG. 27, since the electrostatic chuck ESC itself is electrically coupled to the negative electrode of the second power source (reverse-voltage power source) PS2, the electrometer EM for measuring the potential of the electrostatic chuck ESC indicates the potential (−VDD). In short, the potential of the electrostatic chuck ESC changes from the potential (VDD) to the potential (−VDD).

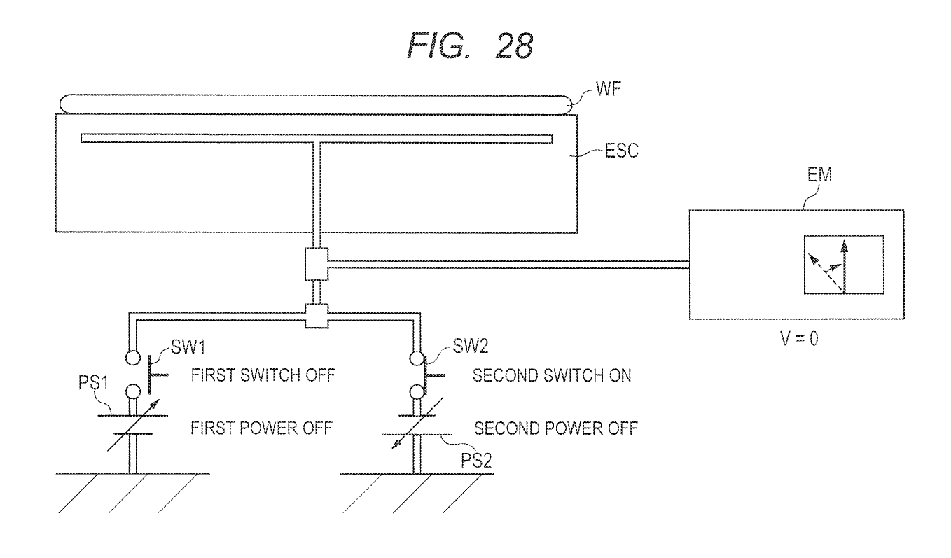

Then, as shown in FIG. 28, the second power source (reverse-voltage power source) PS2 is turned off. In this case, since the electrostatic chuck ESC is electrically coupled to the ground, the plus charges come from the ground to the electrostatic chuck ESC charged with the minus charges, hence to cancel the minus charges and the plus charges. As the result, as shown in FIG. 28, the electrostatic chuck ESC is neutralized. The electrostatic chuck ESC is electrically coupled to the ground, and therefore, the electrometer EM indicates the potential (0 V). In short, the potential of the electrostatic chuck ESC changes from the potential (−VDD) to the potential (0 V).

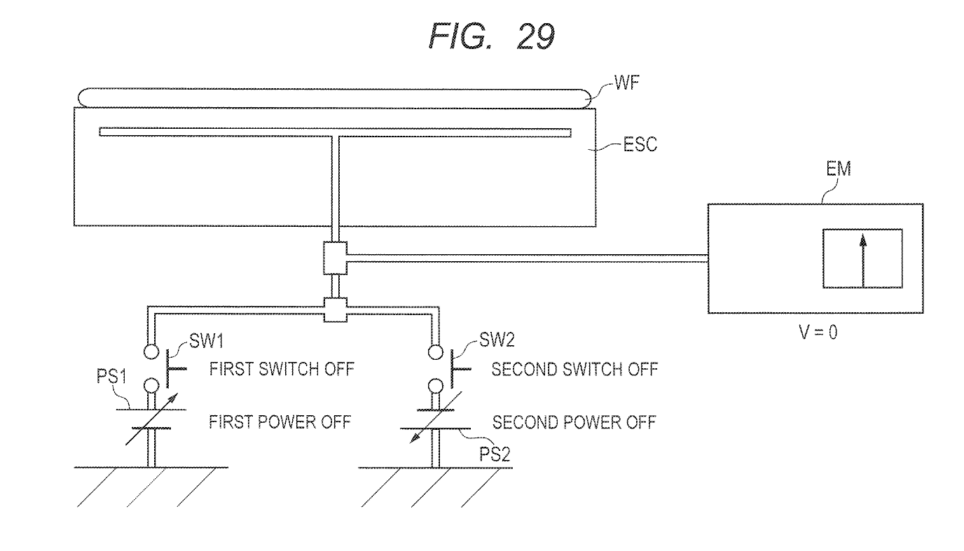

As shown in FIG. 29, the second switch SW2 is turned off (released). According to this, although the electrostatic chuck ESC is in a floating state, the semiconductor wafer WF is completely discharged and also the electrostatic chuck ESC is neutralized; therefore, the electrometer EM keeps the state of indicating the potential (0 V). In other words, when the “charge elimination with reverse voltage” is normally performed, the potential of the electrostatic chuck ESC becomes constant after releasing the second switch SW2.

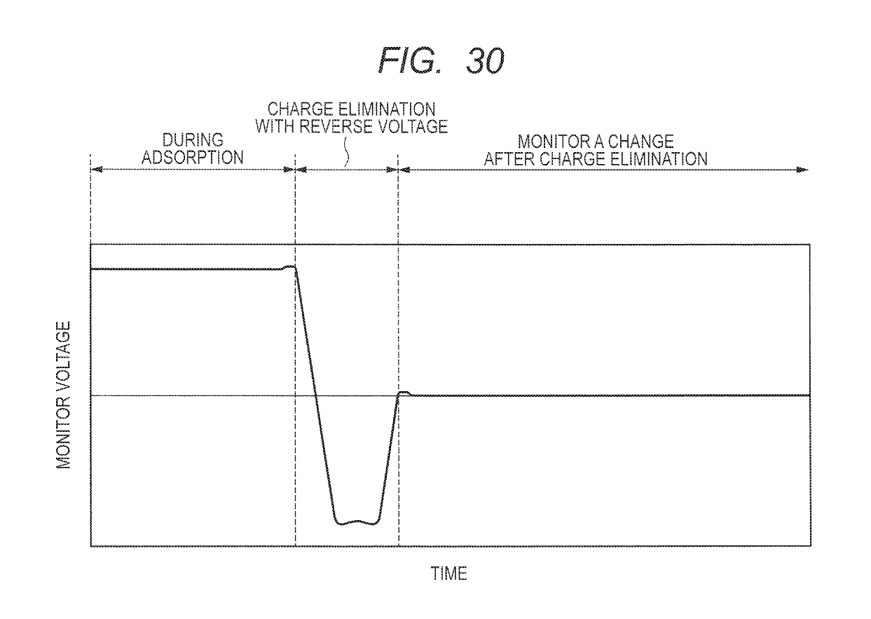

FIG. 30 is a voltage waveform showing a potential change of the electrostatic chuck ESC when the “charge elimination with reverse voltage” is normally performed. As shown in FIG. 30, during the adsorption of the semiconductor wafer, the potential of the electrostatic chuck ESD is the potential (VDD), and then, in the process of the “charge elimination with reverse voltage”, the potential of the electrostatic chuck ESD changes to the potential (−VDD). Upon completion of the “charge elimination with reverse voltage”, after the second switch SW2 is released, the potential of the electrostatic chuck ESD is kept at the potential (0 V). In this case, it can be determined that the “charge elimination with reverse voltage” has been successfully finished in the semiconductor wafer WF and that the semiconductor wafer WF is in the adsorption finishing state (separable state). According to this, it is possible to separate the semiconductor wafer WF from the electrostatic chuck ESC, without causing cracking of the semiconductor wafer WF.

<Separating Operation of Semiconductor Wafer from Electrostatic Chuck> (in the case of insufficient charge elimination)

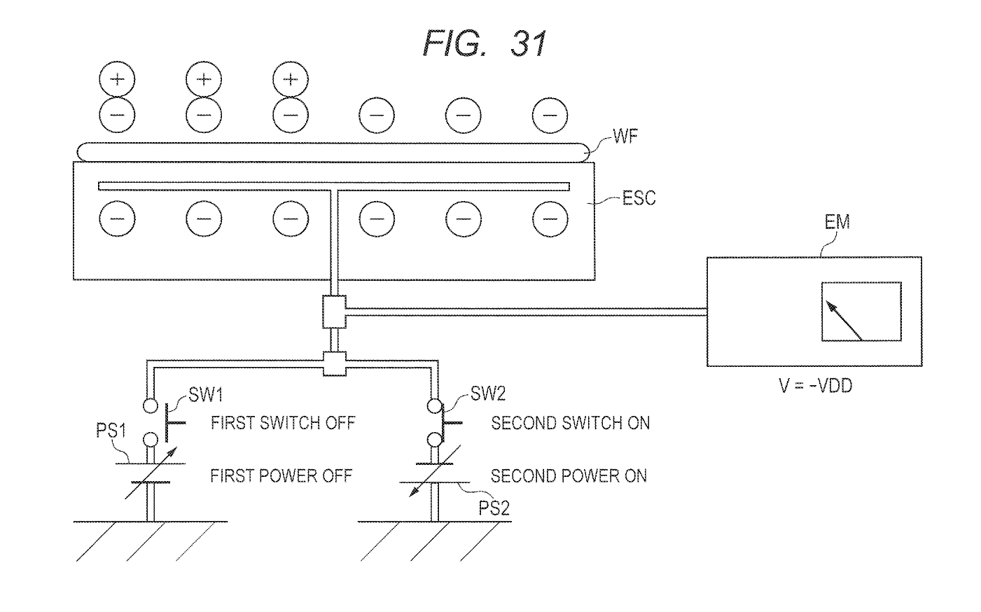

In the case of insufficient “charge elimination with reverse voltage”, however, the potential of the electrostatic chuck ESD behaves differently from the potential of the electrostatic chuck ESD in the above mentioned case of the good “charge elimination with reverse voltage”. This will be described in below. As shown in FIG. 31, upon finishing the processing on the semiconductor wafer WF, the first power source PS1 is turned off and the first switch SW1 is released, hence to make the first power source PS1 and the electrostatic chuck ESC non-conductive. Then, the second power source (reverse-voltage power source) PS2 is turned on and the second switch SW2 is closed, hence to make the second power source (reverse-voltage power source) PS2 and the electrostatic chuck ESC conductive, thereby eliminating the charges of the semiconductor wafer WF adsorbed by the electrostatic chuck ESC (“charge elimination with reverse voltage”).

As shown in FIG. 31, for example, when the “charge elimination with reverse voltage” becomes insufficient, the induction of the plus charges is not enough to cancel all the minus charges charged on the semiconductor wafer WF. Also in this case, since the electrostatic chuck ESC is electrically coupled to the negative electrode of the second power source (reverse-voltage power source), the electrometer EM indicates the potential (−VDD).

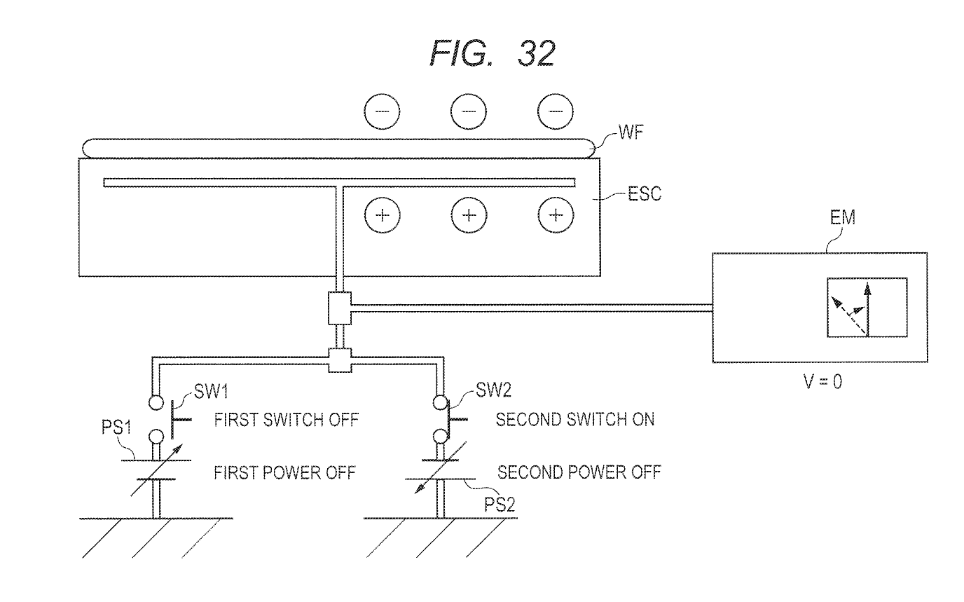

Next, as shown in FIG. 32, with the second switch SW2 turned on, when the second power source (reverse-voltage power source) PS2 is turned off, the electrostatic chuck ESC is electrically coupled to the ground. Therefore, the electrometer EM indicates the potential (0 V). In short, the potential of the electrostatic chuck ESD changes from the potential (−VDD) to the potential (0 V). As shown in FIG. 32, in the case of the insufficient “charge elimination with reverse voltage” of the semiconductor wafer WF, some of the minus charges remain on the semiconductor wafer WF. The plus charges flow from the ground into the electrostatic chuck ESC electrically coupled to the ground and the plus charges corresponding to the minus charges remaining on the semiconductor wafer WF are induced to the electrostatic chuck ESC.

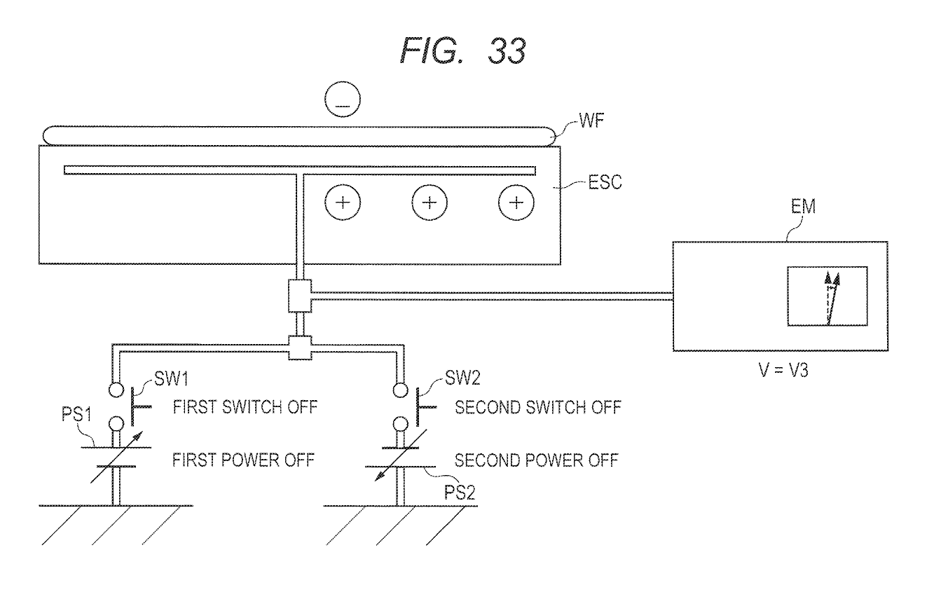

As shown in FIG. 33, the second switch SW2 is released. As the result, the electrostatic chuck ESC is in a floating state. In this state, when the electric charge amount of the minus charges charged on the semiconductor wafer WF does not change, the electrometer EM keeps indicating the potential (0 V); actually, however, some of the minus charges charged on the semiconductor wafer WF disappear because of the natural charge elimination. On the other hand, since the electrostatic chuck ESC is in a floating state, the plus charges charged on the electrostatic chuck ESC never change. As the result, for example, as shown in FIG. 33, the minus charges remaining on the semiconductor wafer WF and the plus charges charged on the electrostatic chuck ESC are unbalanced, and the potential of the electrostatic chuck ESD shifts relatively in a plus direction. In short, in the case of the insufficient “charge elimination with reverse voltage” of the semiconductor wafer WF, the potential of the electrostatic chuck ESD does not keep at the potential (0 V) but changes in a plus direction after releasing the second switch SW2. For example, FIG. 33 shows that the electrometer EM indicates the potential (V3>0).

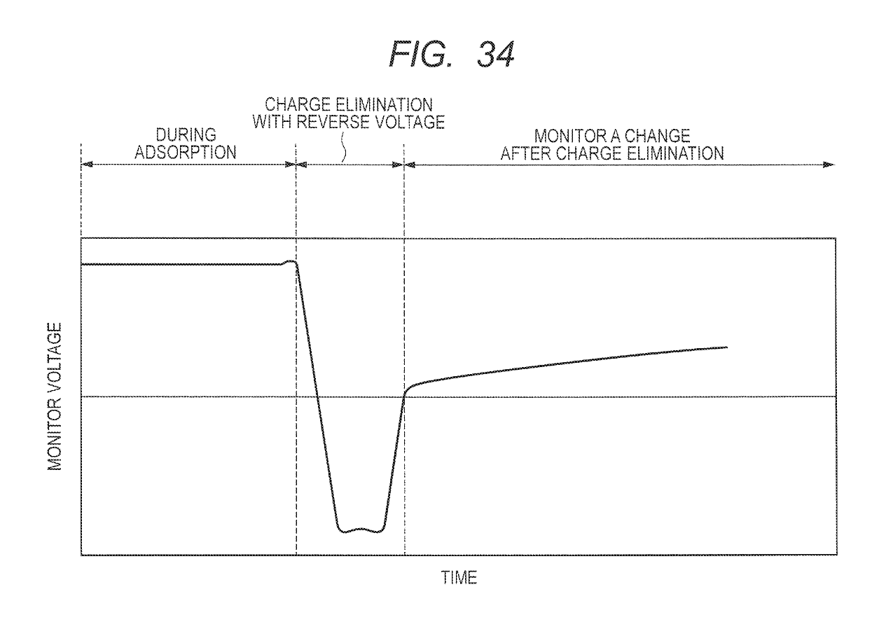

FIG. 34 is a voltage waveform indicating a potential change of the electrostatic chuck ESC in the case of the insufficient “charge elimination with reverse voltage”. As shown in FIG. 34, during the adsorption of the semiconductor wafer WF, the potential of the electrostatic chuck ESD is the potential (VDD) and then, in the process of the “charge elimination with reverse voltage”, the potential of the electrostatic chuck ESD changes to the potential (−VDD). Upon finishing the “charge elimination with reverse voltage”, the potential of the electrostatic chuck ESD changes from the potential (0 V) to in a plus direction after releasing the second switch SW2. In this case of the insufficient “charge elimination with reverse voltage” of the semiconductor wafer WF, the semiconductor wafer WF is not completely discharged, and the semiconductor wafer WF is determined to be in an adsorption finish difficult situation (non-separable state). In this case, when the semiconductor wafer WF is stopped from being separated from the electrostatic chuck ESC, it is possible to prevent the cracking of the semiconductor wafer WF.

As mentioned above, in the case of performing the “charge elimination with reverse voltage”, the “charge elimination with reverse voltage” is finished and the potential of the electrostatic chuck ESD after releasing the second switch SW2 is monitored, hence to determine whether the “charge elimination with reverse voltage” is successively performed or not. Specifically, as is apparent from the comparison between the voltage waveform indicated in FIG. 30 and the voltage waveform indicated in FIG. 34, the potential of the electrostatic chuck ESD keeps at the potential (0 V) after releasing the second switch SW2 in the case of the good “charge elimination with reverse voltage”. On the contrary, in the case of the insufficient “charge elimination with reverse voltage”, the potential of the electrostatic chuck ESD changes after releasing the second switch SW2. Thus, whether or not the “charge elimination with reverse voltage” is successively performed can be determined by monitoring the potential of the electrostatic chuck ESD after releasing the second switch SW2. In other words, by monitoring the potential of the electrostatic chuck ESD after releasing the second switch SW2, it is possible to accurately determine whether or not the semiconductor wafer WF is in the adsorption finishing state (separable state).

As mentioned above, also in the third embodiment, it is necessary to monitor the potential of the electrostatic chuck ESD during a period from the adsorption starting state of the semiconductor wafer WF by the electrostatic chuck ESC to the adsorption finishing state thereof. Particularly, in monitoring the potential of the electrostatic chuck ESD, when the potential of the electrostatic chuck ESD changes after releasing the second switch SW2, the semiconductor wafer WF is determined to be in the adsorption finish difficult state; by adopting this structure, it is possible to prevent the cracking of the semiconductor wafer WF caused by the insufficient “charge elimination with reverse voltage”.

### <Automation Processing by Computer>

In the third embodiment, automation processing by a computer as the charge elimination evaluating device DVA is realized by introducing an algorithm for determining the semiconductor wafer WF to be in the adsorption finish difficult state when the potential of the electrostatic chuck ESD changes after releasing the second switch SW2, in monitoring the potential of the electrostatic chuck ESD. This will be described in below.

### «Functional Structure of Charge Elimination Evaluating Device»

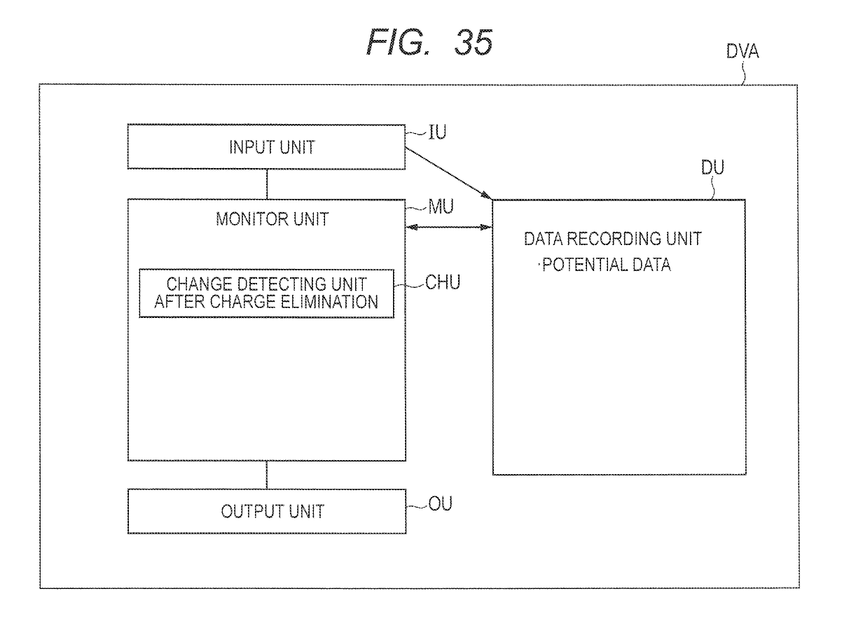

A functional structure of the charge elimination evaluating device DVA according to the third embodiment will be described. FIG. 35 is a view showing the functional block structure of the charge elimination evaluating device DVA according to the third embodiment. In FIG. 35, the charge elimination evaluating device DVA in the third embodiment includes an input unit IU, a monitor unit MU, a change detecting unit after charge elimination CHU, an output unit OU, and a data recording unit DU.

The input unit IU can be coupled to the electrostatic chuck ESC (for example, can be coupled to a terminal (external connection terminal) TE provided in the semiconductor manufacturing device SA), to enter the potential data corresponding to the potential of the electrostatic chuck ESC; and the potential data entered from the input unit IU to the charge elimination evaluating device DVA is stored in the data recording unit DU.

The monitor unit MU is designed to monitor the potential data (potential data entered into the input unit IU) stored in the data recording unit DU. Specifically, the monitor unit MU monitors the potential data entered from the input unit IU, during a period from the adsorption staring state of the semiconductor wafer WF by the electrostatic chuck ESC to the adsorption finishing state thereof.

The change detecting unit after charge elimination CHU detects the potential of the electrostatic chuck ESD getting constant or changing, after releasing the second switch SW2. Further, the above change detecting unit CHU determines the semiconductor wafer WF to be in the adsorption finishing state when detecting the potential of the electrostatic chuck ESD constant, while when detecting the potential of the electrostatic chuck ESD changing after releasing the second switch SW2, the above change detecting unit CHU determines the semiconductor wafer WF not to be in the adsorption finishing state.

The output unit OU outputs the determination result of the above change detecting unit CHU. Specifically, the above unit OU outputs the data indicating whether or not the semiconductor wafer WF is in the adsorption finishing state (the separable state from the electrostatic chuck ESC) to the semiconductor manufacturing device.

### «Charge Elimination Evaluating Method»

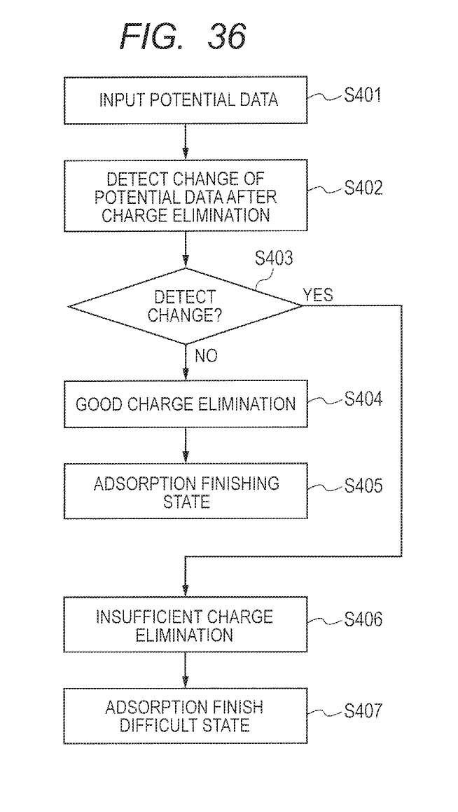

The charge elimination evaluating device DVA in the third embodiment is configured as mentioned above, and hereinafter, a charge elimination evaluating method using the charge elimination evaluating device DVA will be described with reference to the drawings. FIG. 36 is a flow chart showing a flow of the charge elimination evaluating method according to the third embodiment. At first, the charge elimination evaluating device DVA enters the potential data output from the terminal TE of the semiconductor manufacturing device SA through the input unit IU (S401). Then, the monitor unit MU in the charge elimination evaluating device DVA monitors the potential data entered from the input unit IU to the charge elimination evaluating device DVA, during a period from the adsorption starting state of the semiconductor wafer WF by the electrostatic chuck ESC to the adsorption finishing state thereof.

The change detecting unit after charge elimination CHU in the charge elimination evaluating device DVA detects the potential of the electrostatic chuck ESD getting constant or changing, after releasing the second switch SW2 (S402). When the above change detecting unit CHU detects the potential of the electrostatic chuck ESD constant (S403), it determines that the “charge elimination with reverse voltage” of the semiconductor wafer WF is good (S404) and that the semiconductor wafer WF is in the adsorption finishing state (S405). On the other hand, the above change detecting unit CHU detects the potential of the electrostatic chuck ESD changing (S403), after releasing the second switch SW2, it determines that the “charge elimination with reverse voltage” of the semiconductor wafer WF is insufficient (S406) and that the semiconductor wafer WF is not in the adsorption finish difficult state (S407).

Then, the output unit OU in the charge elimination evaluating device DVA outputs the determination result of the above change detecting unit CHU to the semiconductor manufacturing device SA. Then, for example, upon receipt of the data indicating whether or not the semiconductor wafer WF is in the adsorption finishing state (separable state from the electrostatic chuck ESC) from the output unit OU in the charge elimination evaluating device DVA, the semiconductor manufacturing device SA performs separation of the semiconductor wafer WF from the electrostatic chuck ESC or a stop of the separation, based on the above data. According to this, in the third embodiment, it is possible to avoid the semiconductor wafer WF from forcedly being separated from the electrostatic chuck ESC in an insufficient charge elimination state. In short, according to the third embodiment, the state of the “charge elimination with reverse voltage” on the semiconductor wafer WF can be accurately determined; as the result, only in the case of the good “charge elimination with reverse voltage” of the semiconductor wafer WF, the semiconductor wafer WF can be separated from the electrostatic chuck ESC, thereby avoiding the cracking of the semiconductor wafer WF effectively. As mentioned above, the charge elimination evaluating method according to the third embodiment can be realized.

### Fourth Embodiment

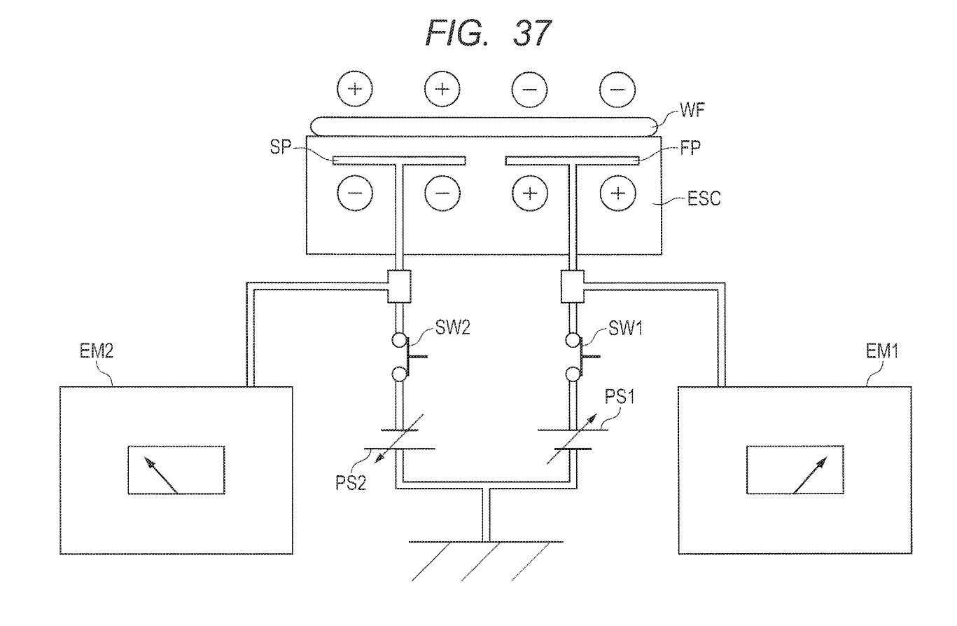

In a fourth embodiment, an example of adopting the technical idea to a so-called “bipolar” electrostatic chuck ESC will be described. FIG. 37 is a view showing a schematic structure of a semiconductor manufacturing device according to the fourth embodiment. As shown in FIG. 37, the semiconductor manufacturing device according to the fourth embodiment includes an electrostatic chuck ESC and a semiconductor wafer WF is arranged on the electrostatic chuck ESC. Here, the electrostatic chuck ESC according to the fourth embodiment is formed by a “bipolar” electrostatic chuck ESC. Specifically, as shown in FIG. 37, the electrostatic chuck ESC according to the fourth embodiment includes a first electrode arranged in a first portion F and a second electrode arranged in a second portion SP. The first electrode is coupled to the power source PS1 through the first switch SW1 and the second electrode is coupled to the power source PS2 through the second switch SW2. Here, the polarity of the power source PS2 is opposite to the polarity of the power source PS1.

In the semiconductor manufacturing device according to the fourth embodiment, at first the power source PS1 is turned on and the first switch SW1 is closed, hence to make the power source PS1 and the first portion FP (first electrode) of the electrostatic chuck ESC conductive. Then, in the semiconductor manufacturing device according to the fourth embodiment, the power source PS2 is turned on and the second switch SW2 is closed, hence to make the power source PS2 and the second portion SP (second electrode) of the electrostatic chuck ESC conductive. According to this, the semiconductor wafer WF is adsorbed by the electrostatic chuck ESC (refer to FIG. 37).

Here, the power source PS1 and the power source PS2 are designed to have reverse polarities; when the semiconductor wafer WF is adsorbed by the electrostatic chuck ESC, plus charges are induced to the first portion FP (first electrode) of the electrostatic chuck ESC, while minus charges are induced to the second portion SP (second electrode) of the electrostatic chuck ESC. As the result, in the semiconductor wafer WF, the minus charges are induced to the first region corresponding to the first portion FP (first electrode) of the electrostatic chuck ESC, and the plus charges are induced to the second region corresponding to the second portion SP (second electrode) of the electrostatic chuck ESC. According to this, the semiconductor wafer WF is adsorbed by the “bipolar” electrostatic chuck ESC thanks to the electrostatic attraction generated between the first portion FP (first electrode) of the electrostatic chuck ESC and the first region of the semiconductor wafer WF and the electrostatic attraction generated between the second portion SP (second electrode) of the electrostatic chuck ESC and the second region of the semiconductor wafer WF.

As shown in FIG. 37, the first portion FP (first electrode) of the electrostatic chuck ESC is electrically coupled to the electrometer EM1 and the second portion SP (second electrode) of the electrostatic chuck ESC is electrically coupled to the electrometer EM2.

Then, in the fourth embodiment, the power source PS1 and the power source PS2 are both turned off. The first switch SW1 is released to make the power source PS1 and the electrostatic chuck ESC non-conductive and the second switch SW2 is released to make the power source PS2 and the electrostatic chuck ESC non-conductive. As the result, the first portion FP (first electrode) of the electrostatic chuck ESC is in a floating state and the second portion SP (second electrode) of the electrostatic chuck ESC is also in a floating state. Also in the fourth embodiment, the monitoring process is performed to monitor the potential of the electrostatic chuck ESD from the adsorption starting state of the semiconductor wafer WF by the electrostatic chuck ESC to the adsorption finishing state thereof. The monitoring process according to the fourth embodiment includes a determination process of determining the semiconductor wafer WF to arrive at the adsorption finishing state when the potential of the first portion FP (first electrode) of the electrostatic chuck ESC is within a predetermined range and the potential of the second portion SP (second electrode) of the electrostatic chuck ESC is within a predetermined range.

FIG. 38 is a view showing together one example of a waveform obtained when the electrometer EM1 monitors the potential of the first portion FP (first electrode) of the electrostatic chuck ESC and one example of a waveform obtained when the electrometer EM2 monitors the potential of the second portion SP (second electrode) of the electrostatic chuck ESC, according to the fourth embodiment. In FIG. 38, when the potential of the first portion FP (first electrode) of the electrostatic chuck ESC is within a predetermined range and the potential of the second portion SP (second electrode) of the electrostatic chuck ESC is within a predetermined range, based on the waveforms monitored by the electrometer EM1 and the electrometer EM2, the semiconductor wafer WF can be determined to arrive at the adsorption finishing state. In other words, even in the case of using the “bipolar” electrostatic chuck ESC according to the fourth embodiment, when the both potentials of the first portion FP (first electrode) of the electrostatic chuck ESC and the second portion SP (second electrode) of the electrostatic chuck ESC take a constant value, it is possible to determine that the charge elimination processing of the semiconductor wafer WF is completely finished and that the semiconductor wafer WF arrives at the adsorption finishing state.

According to this, also in the fourth embodiment, similarly to the first embodiment, it is possible to avoid the semiconductor wafer WF from being forcedly separated from the electrostatic chuck ESC in the insufficient state of charge elimination. In short, also according to the fourth embodiment, whether or not the charge elimination of the semiconductor wafer WF has been completely finished can be accurately determined; as the result, after completely finishing the charge elimination processing of the semiconductor wafer WF, the semiconductor wafer WF can be separated from the electrostatic chuck ESC, hence to avoid the cracking of the semiconductor wafer WF effectively.

### Fifth Embodiment

The technical idea having been described in the first to the fourth embodiments can be effectively applied, for example, to a process of etching an insulating film during the manufacturing process of a semiconductor device. This is because as the result of forming the insulating film from an insulating material (dielectric material), electric charges are easy to be attached to the insulating film, in the plasma etching process using a plasma etching device (semiconductor manufacturing device), and therefore, cracking of a semiconductor wafer WF becomes remarkable when separating the semiconductor wafer WF from the electrostatic chuck ESC.

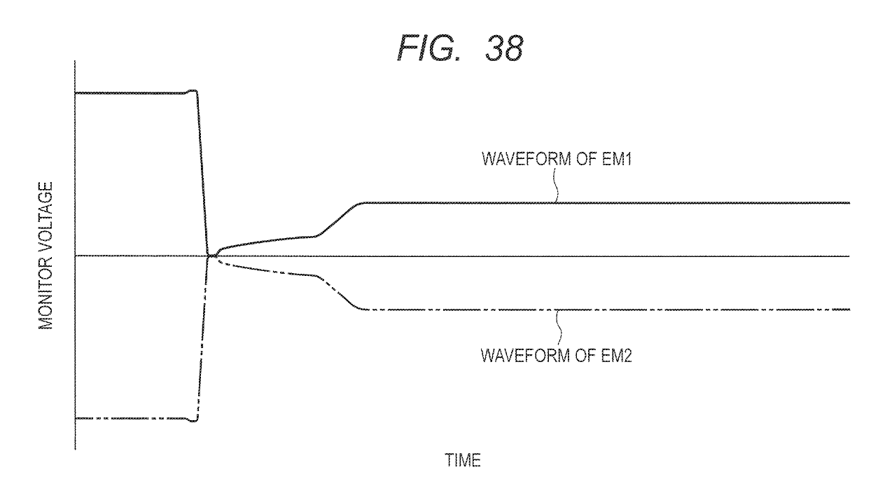

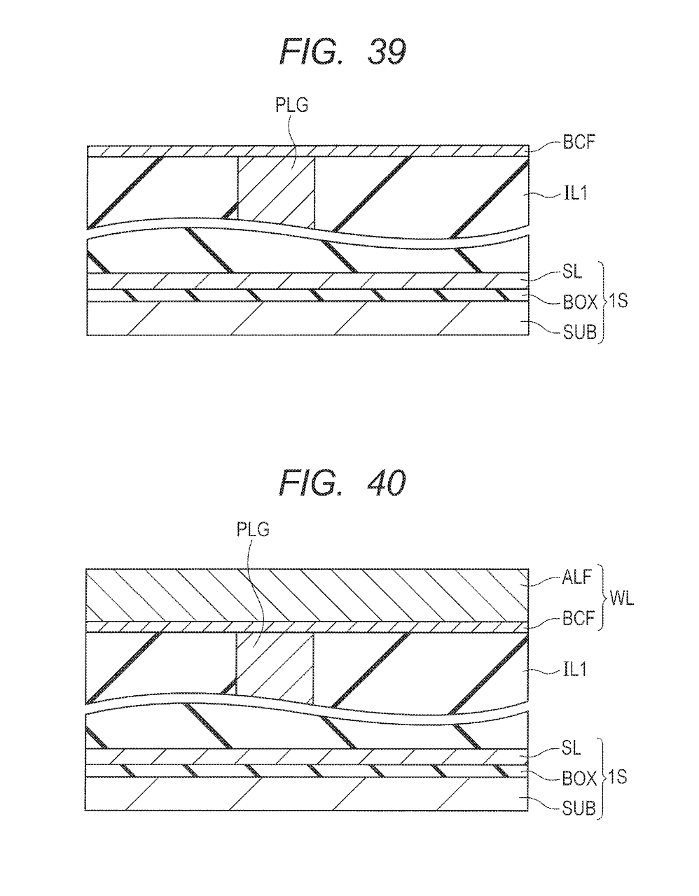

One example of the manufacturing process of a semiconductor device including the process of etching the insulating film will be described. At first, in FIG. 39, for example, an interlayer insulating film IL1 made of silicon oxide film is formed above a Silicon On Insulator (SOI) substrate 1S including a supporting substrate SUB, an embedded insulating layer BOX, and a semiconductor layer (silicon layer) SL, and a plug PLG is formed in this interlayer insulating film IL1 . As shown in FIG. 39, a barrier conductor film BCF is formed on the interlayer insulating film IL1 having the plug PLG. The barrier conductor film BCF can be formed of, for example, titanium/titanium nitride film, for example, according to the sputtering.

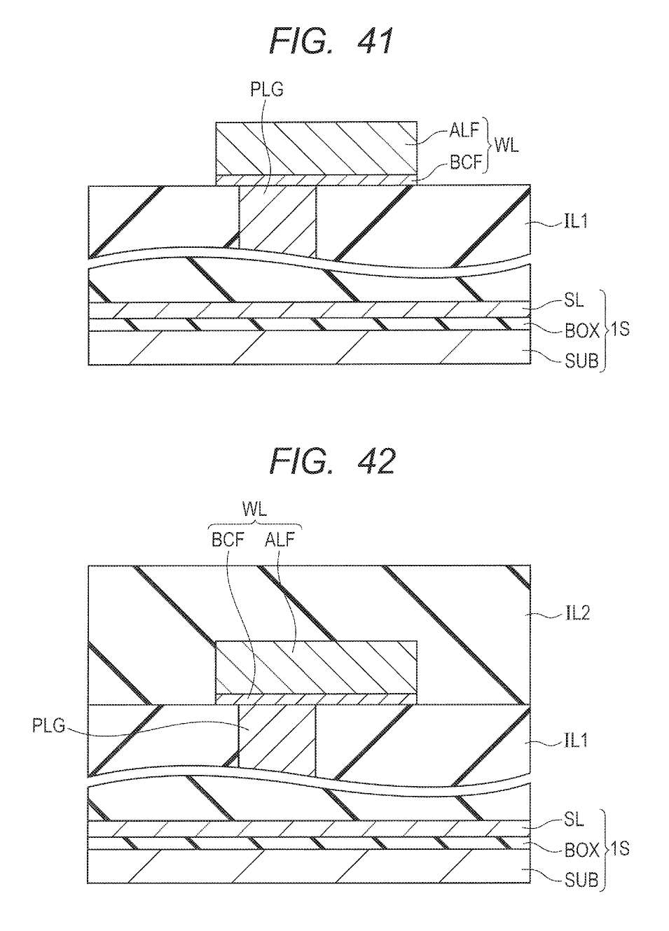

As shown in FIG. 40, an aluminum film ALF is formed on the barrier conductor film BCF. The aluminum film ALF can be formed, for example, according to the sputtering. As shown in FIG. 41, the aluminum film ALF and the barrier conductor film BCF are patterned according to the photolithography and etching technique. Thus, a wiring WL including the barrier conductor film BCF and the aluminum film ALF can be formed.

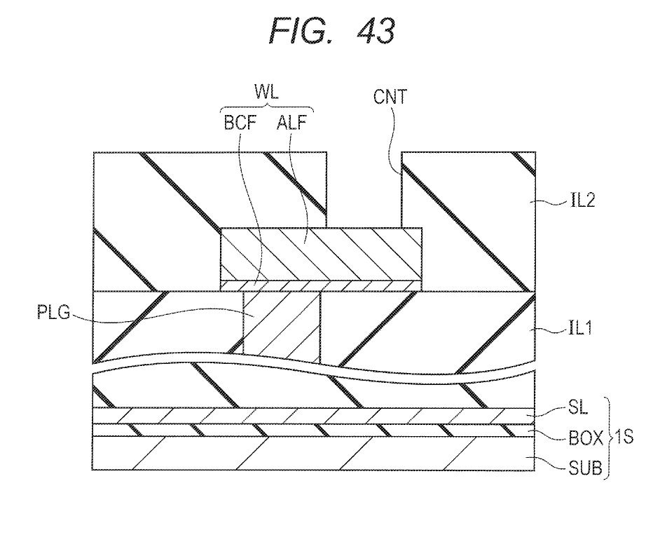

Continuously, as shown in FIG. 42, for example, an interlayer insulating film IL2 made of silicon oxide film is formed on the interlayer insulating film IL1 where the wiring WL is formed, to cover the wiring WL. The interlayer insulating film IL2 can be formed, for example, according to the Chemical Vapor Deposition (CVD). Then, as shown in FIG. 43, a contact hole CNT is formed in the interlayer insulating film IL2 according to the photolithography and etching technique. Here, the process of forming the contact hole CNT in the interlayer insulating film IL2 corresponds to the process of etching the insulating film (interlayer insulating film); by adopting the technical idea having been described in the above mentioned first to fourth embodiments to this process of etching the insulating film, it is possible to effectively avoid cracking of the semiconductor wafer WF caused by the electrification of the semiconductor wafer WF.

Although the process later than this is omitted, multilayer wiring is formed, for example, after a plug is formed by embedding a conductive film in the contact hole CNT formed in the interlayer insulating film IL2.

As mentioned above, the manufacturing process of a semiconductor device according to the fifth embodiment includes the process of forming the wiring WL in the semiconductor wafer WF (SOI substrate 1S), the process of forming the insulating film (interlayer insulating film IL2) to cover the wiring WL, and the process of forming the contact hole CNT arriving at the wiring WL in the insulating film (interlayer insulating film IL2). Here, in the fifth embodiment, the technical idea having been described in the above first to fourth embodiments is adopted to the process of forming the contact hole CNT arriving at the wiring WL in the insulating film (interlayer insulating film IL2). According to the manufacturing process of the semiconductor device in the fifth embodiment, it is possible to effectively avoid the cracking of the semiconductor wafer WF caused by the electrification of the semiconductor wafer WF.

Further, in the fifth embodiment, the SOI substrate 1S is used and in the SOI substrate 1S, the embedded insulating layer BOX is easily charged with electricity. That is why the technical idea having been described in the above first to fourth embodiments is effective especially when forming the semiconductor wafer WF from the SOI substrate 1S, like the fifth embodiment.

As set forth hereinabove, although the invention made by the inventor et al. has been described specifically based on the embodiments, it is needless to say that the invention is not restricted to the above but that various modifications are possible without departing from its idea.

The embodiments include the following forms.

### (Appendix 1)

A charge elimination evaluating device connectable to a semiconductor manufacturing device of processing a semiconductor wafer, for evaluating elimination of charges charged on the semiconductor wafer,
wherein the semiconductor manufacturing device includes
an electrostatic chuck that adsorbs the semiconductor wafer,
a power source electrically connectable to the electrostatic chuck, and
a first switch that switches conductivity or non-conductivity between the power source and the electrostatic chuck,
the charge elimination evaluating device including:
an input unit that is provided between the electrostatic chuck and the first switch in a connectable way, for entering potential data corresponding to a potential of the electrostatic chuck;
a monitor unit that monitors the potential data entered from the input unit, during a period from an adsorption starting state of the semiconductor wafer by electrostatic chuck to an adsorption finishing state thereof;
a judging unit that determines the semiconductor wafer to be in the adsorption finishing state when the potential data monitored by the monitor unit is within a predetermined range; and
an output unit that outputs the determination result of the judging unit.

### (Appendix 2)

A charge elimination evaluating method of evaluating elimination of charges charged on a semiconductor wafer, using a charge elimination evaluating device coupled to a semiconductor manufacturing device of processing the semiconductor wafer,
wherein the semiconductor manufacturing device includes
an electrostatic chuck that adsorbs the semiconductor wafer,
a power source electrically connectable to the electrostatic chuck, and
a first switch that switches conductivity or non-conductivity between the power source and the electrostatic chuck,
the charge elimination evaluating method including the following steps of:
(a) entering potential data corresponding to a potential of the electrostatic chuck to the charge elimination evaluating device coupled between the electrostatic chuck and the first switch;
(b) monitoring the potential data entered in the step (a), from an adsorption starting state of the semiconductor wafer by the electrostatic chuck to an adsorption finishing state thereof;
(c) determining the semiconductor wafer to be in the adsorption finishing state when the potential data monitored in the step (b) is within a predetermined range; and
(d) outputting the determination result of the step (c).

### (Appendix 3)

A charge elimination evaluating program for executing a charge elimination evaluating method of evaluating elimination of charges charged on a semiconductor wafer, using a computer connectable to a semiconductor manufacturing device of processing the semiconductor wafer,
wherein the semiconductor manufacturing device includes
an electrostatic chuck that adsorbs the semiconductor wafer,
a power source electrically connectable to the electrostatic chuck, and
a first switch that switches conductivity or non-conductivity between the power source and the electrostatic chuck,
the charge elimination evaluating program making the computer execute the following processing of:
(a) entering potential data corresponding to a potential of the electrostatic chuck to the charge elimination evaluating device coupled between the electrostatic chuck and the first switch;
(b) monitoring the potential data entered in the step (a), from an adsorption starting state of the semiconductor wafer by the electrostatic chuck to an adsorption finishing state thereof;
(c) determining the semiconductor wafer to be in the adsorption finishing state when the potential data monitored in the step (b) is within a predetermined range; and
(d) outputting the determination result of the step (c).

### (Appendix 4)

A computer readable recording medium with the charge elimination evaluating program according to the appendix 3 recorded.

What is claimed is:

1. A manufacturing method of a semiconductor device having a step of performing processing on a semiconductor wafer using a semiconductor manufacturing device,
the semiconductor manufacturing device including
an electrostatic chuck that adsorbs the semiconductor wafer,
a power source electrically connectable to the electrostatic chuck, and
a first switch that switches conductivity or non-conductivity between the power source and the electrostatic chuck,
the above manufacturing method comprising the following steps of:
(a) turning on the power source and closing the first switch, to make the power source and the electrostatic chuck conductive, hence to adsorb the semiconductor wafer by the electrostatic chuck;
(b) after the step (a), performing the processing on the semiconductor wafer;
(c) after the step (b), turning off the power source;
(d) after the step (b), releasing the first switch, to make the power source and the electrostatic chuck non-conductive; and
(e) monitoring a potential of the electrostatic chuck from an adsorption starting state of the semiconductor wafer by the electrostatic chuck to an adsorption finishing state thereof,
wherein the above step (e) further includes a step of determining the semiconductor wafer to be in the adsorption finishing state, when the potential of the electrostatic chuck is within a predetermined range.

2. The method according to claim 1, further comprising
a step of eliminating charges charged on the semiconductor wafer after the step (d).

3. The method according to claim 2,
wherein plasma is used in the step of eliminating charges charged on the semiconductor wafer.

4. The method according to claim 3,
wherein the step (e) further includes a step of specifying a charge elimination time of the semiconductor wafer, based on a change of the potential of the electrostatic chuck.

5. The method according to claim 4, further comprising
a step of optimizing a charge eliminating condition in the step of eliminating charges charged on the semiconductor wafer, based on the charge elimination time.

6. The method according to claim 1,
the semiconductor manufacturing device further including:
a reverse-voltage power source electrically connectable to the electrostatic chuck and having a reverse polarity to the power source, and
a second switch that switches conductivity or non-conductivity between the reverse-voltage power source and the electrostatic chuck,
the above method further comprising the following steps of:
after the step (c) and the step (d), turning on the reverse-voltage power source and closing the second switch, to make the reverse-voltage power source and the electrostatic chuck conductive, hence to eliminate the charges on the semiconductor wafer adsorbed by the electrostatic chuck; and
after eliminating the charges on the semiconductor wafer, releasing the second switch, to make the reverse-voltage power source and the electrostatic chuck non-conductive,
wherein the step (e) includes a step of determining the semiconductor wafer to be in the adsorption finishing state when the potential of the electrostatic chuck becomes constant after releasing the second switch, while determining the semiconductor wafer not to be in the adsorption finishing state when the potential of the electrostatic chuck changes after releasing the second switch.

7. The method according to claim 1,
the semiconductor manufacturing device further including:
a reverse-voltage power source electrically connectable to the electrostatic chuck and having a reverse polarity to the power source, and
a second switch that switches conductivity or non-conductivity between the reverse-voltage power source and the electrostatic chuck,
wherein in the step (a), the power source is turned on and the first switch is closed, to make the power source and a first portion of the electrostatic chuck conductive, and at the same time, the reverse-voltage power source is turned on and the second switch is closed, to make the reverse-voltage power source and a second portion of the electrostatic chuck conductive, thereby adsorbing the semiconductor wafer by the electrostatic chuck,
wherein in the step (c), further the reverse-voltage power source is turned off,
wherein in the step (d), further the second switch is released, to make the reverse-voltage power source and the electrostatic chuck non-conductive,
wherein in the step (e), when the potential of the first portion of the electrostatic chuck is within a predetermined range and the potential of the second portion of the electrostatic chuck is within a predetermined range, the semiconductor wafer is determined to be in the adsorption finishing state.

8. The method according to claim 2,
wherein the steps from the above (a) to (e) are performed on each of the plural semiconductor wafers,
the above method further comprising:
a step of adjusting a charge eliminating condition in the step of eliminating the charges charged on the semiconductor device, based on a plurality of potential waveforms of the electrostatic chuck obtained by starting the processing of the semiconductor wafers.

9. The method according to claim 1,
the semiconductor manufacturing device further including a monitor unit that monitors a potential of the electrostatic chuck from the adsorption starting state of the semiconductor wafer by the electrostatic chuck to the adsorption finishing state thereof,
wherein the monitor unit is provided between the electrostatic chuck and the first switch.

10. The method according to claim 1,
the semiconductor manufacturing device further including an external connection terminal provided between the electrostatic chuck and the first switch,
wherein the external connection terminal is provided outside of the semiconductor manufacturing device in a connectable way to the monitor unit that monitors the potential of the electrostatic chuck from the adsorption starting state of the semiconductor wafer by the electrostatic chuck to the adsorption finishing state thereof.

11. The method according to claim 1,
wherein in the step of etching an insulating film, the steps from the above (a) to (e) are performed.

12. The method according to claim 1, further comprising:
(A1) forming a wiring on the semiconductor wafer;
(A2) forming an insulating film to cover the wiring; and
(A3) forming a contact hole arriving at the wiring in the insulating film,
wherein in the step of forming the contact hole arriving at the wiring in the insulating film, the steps from the above (a) to (e) are performed.

13. The method according to claim 12,
wherein the step (A3) is a plasma etching process.

14. The method according to claim 1,
wherein the semiconductor manufacturing device is a plasma etching device.

15. The method according to claim 1,
wherein the semiconductor wafer includes
a supporting substrate,
an embedded insulating layer formed on the supporting substrate, and
a semiconductor layer formed on the embedded insulating layer.
